(19) United States
(12) Patent Application Publication
(10) Pub. No.: US 2008/0116933 A1
(43) Pub. Date: May 22, 2008

(54) Integrated circuit device and electronic instrument

(75) Inventor: Hisanobu Ishiyama, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, TOKYO (JP)

(21) Appl. No.: 11/984,078

(22) Filed: Nov. 13, 2007

(30) Foreign Application Priority Data
Nov. 22, 2006 (JP) 2006-315803

(51) Int. Cl. H03K 19/0175

(52) U.S. Cl. 326/62

(57) ABSTRACT

An integrated circuit device includes data pads, I/O circuits, each of the I/O circuits respectively receiving a CMOS level data signal from one of the data pads, a high-speed I/F circuit block that includes a physical layer circuit and transfers data through a serial bus using differential signals, and a logic circuit block that receives signals from the high-speed I/F circuit block and the I/O circuits. At least some of the data pads are set to be shared pads, and first and second signals forming the differential signals are input to a receiver circuit of the physical layer circuit through the shared pads.

Japanese Patent Application No. 2006-315803 filed on Nov. 22, 2006, is hereby incorporated by reference in its entirety.

### BACKGROUND OF THE INVENTION

The present invention relates to an integrated circuit device and an electronic instrument.

In recent years, a high-speed serial transfer such as low voltage differential signaling (LVDS) has attracted attention as an interface aiming at reducing EMI noise or the like (see JP-A-2001-222249). In such a high-speed serial transfer, data is transferred by causing a transmitter circuit to transmit serialized data using differential signals and causing a receiver circuit to differentially amplify the differential signals.

An ordinary portable telephone includes a first instrument section provided with buttons for inputting a telephone number and characters, a second instrument section provided with a liquid crystal display (LCD) and a camera device, and a connection section (e.g., hinge) which connects the first and second instrument sections. Therefore, the number of interconnects passing through the connection section can be reduced by transferring data between a first circuit board provided in the first instrument section and a second circuit board provided in the second instrument section by a high-speed serial transfer using small-amplitude differential signals.

A display driver (LCD driver) is known as an integrated circuit device which drives a display panel such as a liquid crystal panel. In order to realize a high-speed serial transfer between the first and second instrument sections, a high-speed interface circuit which transfers data through a serial bus must be incorporated in the display driver.

On the other hand, a display driver generally utilizes a micro processor unit (MPU) interface (i.e., MPU parallel interface) as an interface between the display driver and a host processor. Since interconnects formed on a glass substrate on which the display driver is mounted are designed for such an MPU interface, replacement of the MPU interface with the high-speed serial interface has progressed to only a small extent.

### SUMMARY

According to one aspect of the invention, there is provided an integrated circuit device comprising:

a plurality of data pads;

a plurality of I/O circuits, each of the plurality of I/O circuits respectively receiving a CMOS level data signal from each of the plurality of data pads;

a high-speed interface circuit block that includes a physical layer circuit and transfers data through a serial bus using differential signals; and

a logic circuit block that receives signals from the high-speed interface circuit block and the plurality of I/O circuits;

at least some of the plurality of data pads being set to be shared pads, and first and second signals forming the differential signals being input to the physical layer circuit through the shared pads.

According to another aspect of the invention, there is provided an electronic instrument comprising:

the above integrated circuit device; and

a display panel driven by the integrated circuit device.

### BRIEF DESCRIPTION OF THE SEVERAL VIEWS OF THE DRAWING

FIG. 1 shows an example of a display panel on which an integrated circuit device according to one embodiment of the invention is mounted.

FIG. 2 is a view illustrative of a pad sharing method.

FIGS. 3A and 3B are views illustrative of a pad sharing method according to one embodiment of the invention.

FIG. 4 shows an arrangement example of I/O circuits and receiver circuits.

FIG. 5 shows a configuration example of an I/O circuit.

FIGS. 6A and 6B show MPU interface signal waveform examples.

FIGS. 7A and 7B show configuration examples of a high-speed I/F circuit and a physical layer circuit.

FIG. 8 shows an example of a signal switching method.

FIGS. 9A and 9B are views illustrative of a test process when using a signal switching method.

FIGS. 10A and 10B are views showing an example of a mask switching method.

FIG. 11 is a view illustrative of a test process when using a mask switching method.

FIG. 12 is a view illustrative of data transfer to a subdisplay panel.

FIG. 13 is a view illustrative of a pad arrangement method when transferring data to a subdisplay panel.

FIG. 14 shows a detailed layout example of an integrated circuit device.

FIG. 15 shows a circuit configuration example of an integrated circuit device.

FIG. 16 shows an arrangement configuration example of an integrated circuit device.

FIGS. 17A and 17B show planar layout examples of an integrated circuit device.

FIGS. 18A and 18B show examples of a cross-sectional view of an integrated circuit device.

FIGS. 19A and 19B are views illustrative of a block division method for a memory and a data driver.

FIG. 20 is a view illustrative of a method of reading image data two or more times in one horizontal scan period.

FIG. 21 shows an arrangement example of data drivers and driver cells.

FIGS. 22A and 22B show configuration examples of an electronic instrument.

### DETAILED DESCRIPTION OF THE EMBODIMENT

Aspects of the invention may provide an integrated circuit device which facilitates incorporation of a high-speed serial interface, and an electronic instrument including the same.

According to one embodiment of the invention, there is provided an integrated circuit device comprising:

a plurality of data pads;

a plurality of I/O circuits, each of the plurality of I/O circuits respectively receiving a CMOS level data signal from each of the plurality of data pads;

a high-speed interface circuit block that includes a physical layer circuit and transfers data through a serial bus using differential signals; and

a logic circuit block that receives signals from the high-speed interface circuit block and the plurality of I/O circuits;

at least some of the plurality of data pads being set to be shared pads, and first and second signals forming the differential signals being input to the physical layer circuit through the shared pads.

According to this embodiment, the I/O circuit receives the CMOS level signal, and the physical layer circuit receives the differential signals of which the amplitude is smaller than that of the CMOS level signal. Some of the I/O circuit data pads are set to be shared pads, and the first and second signals of the differential signals can be input to the physical layer circuit through the shared pads. Therefore, since the shared pad can be used not only for CMOS level interface but also for high-speed serial interface, incorporation of the high-speed serial interface can be facilitated.

In the integrated circuit device,

the physical layer circuit may include a receiver circuit to which the first and second signals forming the differential signals are input; and

at least the receiver circuit of the physical layer circuit may be disposed in an I/O region in which the plurality of I/O circuits are disposed.

According to this configuration, since the receiver circuit can be disposed by effectively utilizing the I/O region, the layout efficiency can be increased.

In the integrated circuit device,

the plurality of I/O circuits may include a first I/O circuit and a second I/O circuit; the shared pads including a first shared pad and a second shared pad,

the first I/O circuit to which a CMOS level data signal from the first shared pad is input and the second I/O circuit to which a CMOS level data signal from the second shared pad is input may be disposed in the I/O region; and

the receiver circuit may receive a signal input from the first shared pad as the first signal of the differential signals and may receive a signal input from the second shared pad as the second signal of the differential signals.

According to this configuration, the first and second I/O circuits and the receiver circuit can be efficiently disposed in the I/O region.

In the integrated circuit device,

the receiver circuit may be disposed between the first I/O circuit and the second I/O circuit.

This prevents a situation in which noise from the data signal of the I/O circuit is superimposed on the lines of the first and second signals.

In the integrated circuit device,

the shared pads may be connected with the plurality of I/O circuits and a receiver circuit of the physical layer circuit;

the receiver circuit may be disabled in an MPU interface mode in which the shared pads are used as input pads of the CMOS level data signals; and

the plurality of I/O circuits may be disabled in a serial interface mode in which the shared pads are used as input pads of the first and second signals of the differential signals.

According to this configuration, the MPU interface mode and the serial interface mode can be switched by merely controlling disenablement of the I/O circuits and the receiver circuit, whereby the shared pads can be used for MPU interface or serial interface.

In the integrated circuit device,

the integrated circuit device may be set in the MPU interface mode in a test mode in case that the integrated circuit device is set in the serial interface mode in a normal mode; and

the logic circuit block may perform a test process in the test mode based on CMOS level test signals input from the plurality of data pads through the plurality of I/O circuits.

This enables the test process to be performed in the test mode based on the CMOS level test signals, whereby the test efficiency can be increased.

The integrated circuit device may further comprise;

a switching terminal that switches the MPU interface mode and the serial interface mode.

According to this configuration, the MPU interface mode and the serial interface mode can be switched merely by externally controlling the switching terminal.

In the integrated circuit device,

the shared pads and the plurality of I/O circuits may be connected via interconnects when the shared pads are used as input pads of the CMOS level data signals; and

the shared pads and the physical layer circuit may be connected via interconnects when the shared pads are used as input pads of the first and second signals of the differential signals.

According to this configuration, the shared pads can be switched by merely changing the interconnects.

In the integrated circuit device,

when the integrated circuit device is set in a test mode in a state in which the shared pads and the physical layer circuit are connected via the interconnects, the logic circuit block may perform a test process based on CMOS level test signals input through the plurality of I/O circuits from pads among the plurality of data pads other than the shared pads.

According to this configuration, a data transfer in the normal mode can be realized by a high-speed serial transfer using the physical layer circuit, and the test process can be performed in the test mode using the CMOS level signals which can be easily handled.

In the integrated circuit device,

the logic circuit block may receive data received by the high-speed interface circuit block, and may output data signals for driving a subdisplay panel to the subdisplay panel through k-bit (k is a positive integer) data pads among the plurality of data pads other than the shared pads.

According to this configuration, data can be transferred to the subdisplay panel using the k-bit data pads other than the shared pads.

In the integrated circuit device,

the logic circuit block may output data transfer control signals to the subdisplay panel through control pads; and

the k-bit data pads may be disposed between the shared pads and the control pads.

According to this configuration, data can be transferred to the subdisplay panel while preventing the differential signal line from intersecting the data signal line connected to the subdisplay panel.

The integrated circuit device may comprise:

first to Nth circuit blocks (N is an integer equal to or larger than two) disposed along a first direction when a direction from a first side which is a short side of the integrated circuit device toward a third side opposite to the first side is referred to as a first direction and a direction from a second side which is a long side of the integrated circuit device toward a fourth side opposite to the second side is referred to as a second direction;

the first to Nth circuit blocks may include:

at least one data driver block that drives a plurality of data lines of a display panel;

a grayscale voltage generation circuit block that generates grayscale voltages; and

the logic circuit block that transfers grayscale adjustment data for adjusting the grayscale voltage to the grayscale voltage generation circuit block; and

when a direction opposite to the first direction is referred to as a third direction, the grayscale voltage generation circuit block may be disposed in the third direction of the data driver block, and the logic circuit block may be disposed in the first direction of the data driver block.

According to this configuration, since the first to Nth circuit blocks are disposed along the first direction, the width of the integrated circuit device in the second direction can be reduced, whereby a reduction in area can be achieved. Moreover, interconnects can be provided utilizing the free space in the second direction of the grayscale voltage generation circuit block and the logic circuit block, whereby the wiring efficiency can be increased. Furthermore, since the data driver block can be disposed near the center of the integrated circuit device, data signal output lines from the data driver block can be efficiently and simply provided.

The integrated circuit device may further comprise:

first to Nth circuit blocks (N is an integer equal to or larger than two) disposed along a first direction when a direction from a first side which is a short side of the integrated circuit device toward a third side opposite to the first side is referred to as a first direction and a direction from a second side which is a long side of the integrated circuit device toward a fourth side opposite to the second side is referred to as a second direction;

the first to Nth circuit blocks may include:

at least one data driver block that drives a plurality of data lines of a display panel;

a power supply circuit block that generates a power supply voltage; and

the logic circuit block that receives data received by the high-speed interface circuit block and transfers power supply adjustment data for adjusting the power supply voltage to the power supply circuit block; and

when a direction opposite to the first direction is referred to as a third direction, the power supply circuit block may be disposed in the third direction of the data driver block, and the logic circuit block may be disposed in the first direction of the data driver block.

According to this configuration, interconnects can be provided utilizing the free space in the second direction of the power supply circuit block and the logic circuit block, whereby the wiring efficiency can be increased.

According to another embodiment of the invention, there is provided an electronic instrument comprising:

the above integrated circuit device; and

a display panel driven by the integrated circuit device.

Preferred embodiments of the invention are described below in detail. Note that the embodiments described below do not in any way limit the scope of the invention defined by the claims laid out herein. Note that all elements of the embodiments described below should not necessarily be taken as essential requirements for the invention.

1. Display Panel

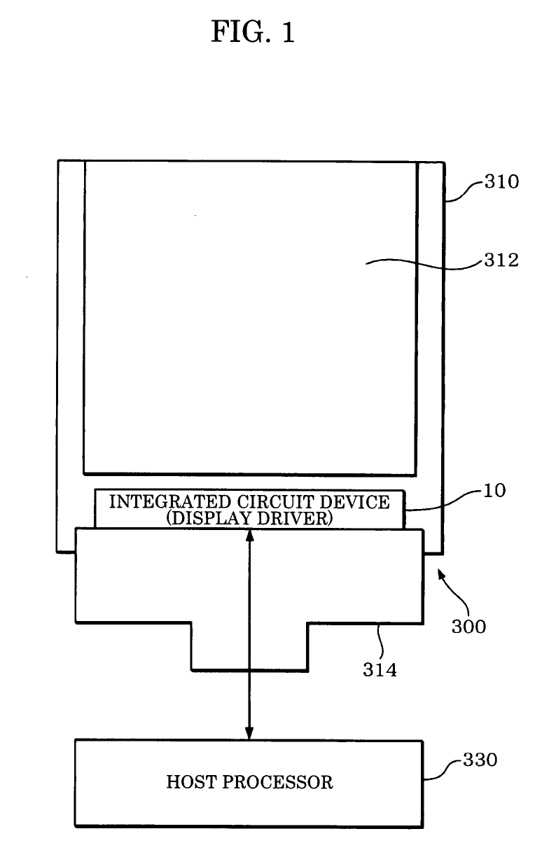

FIG. 1 shows an example of a display panel 300 on which an integrated circuit device 10 (display driver) according to this embodiment is mounted. The display panel 300 includes an array substrate 310 (array glass substrate) and a common substrate (common glass substrate) (not shown). A TFT array section 312 (display section) in which thin film transistors (TFTs) and pixel electrodes are disposed in a matrix is formed on the array substrate 310, and a common electrode is formed on the common substrate. A liquid crystal element (electro-optical element in a broad sense) is sealed between the array substrate 310 (first substrate in a broad sense) and the common substrate (second substrate in a broad sense).

The integrated circuit device 10 is mounted on the array substrate 310 by chip on glass (COG) technology using bumps (gold bumps or resin core bumps), for example. Specifically, bumps provided on the integrated circuit device 10 and terminals provided on the array substrate 310 are electrically connected through an anisotropic conductive film (ACF). A flexible printed circuit (FPC) substrate 314 is connected with the array substrate 310. Input signal lines and output signal lines of the integrated circuit device 10 are provided on the FPC substrate 314 (flexible substrate). The integrated circuit device 10 and a host processor 330 (main substrate on which the host processor 330 is mounted) are connected through signal lines provided on the FPC substrate 314.

2. Shared Pad

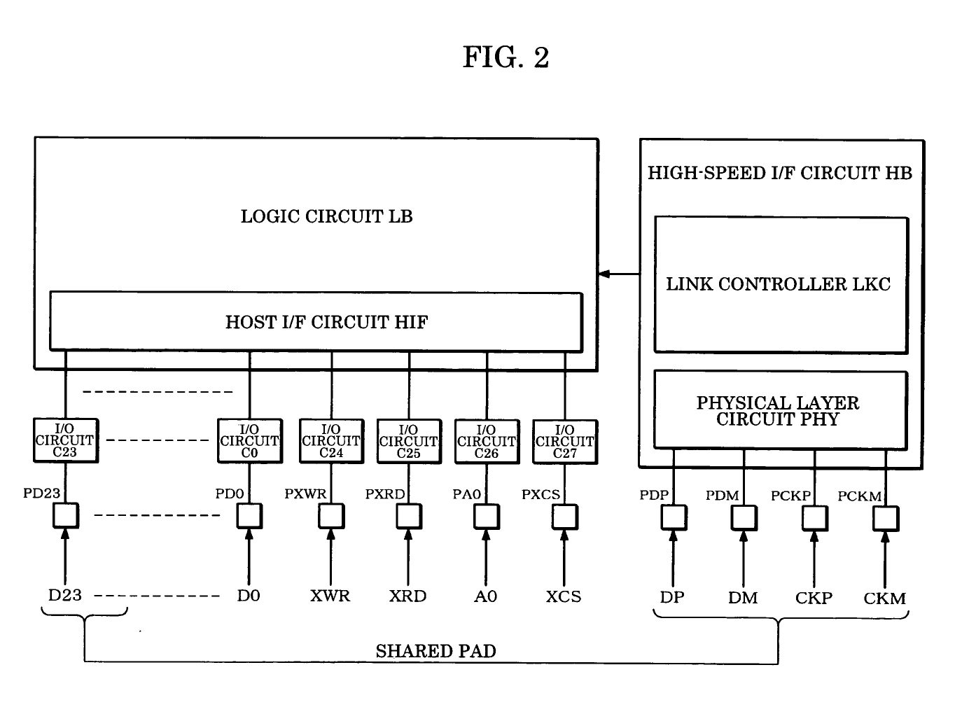

As shown in FIG. 2, the integrated circuit device includes a logic circuit block LB and a high-speed interface (I/F) circuit block HB. The logic circuit block LB includes a host I/F circuit HIF. The host I/F circuit HIF implements a micro processor unit (MPU) interface. The MPU interface (parallel interface or host interface) utilizes data D0 to D23, a write signal XWR, a read signal XRD, an address 0 signal A0, and a chip select signal XCS (X″ means a negative logic). Data pads PD23 to PD0 and control pads PXWR, PXRD, PA0, and PXCS are provided in order to implement the MPU interface.

The high-speed I/F circuit block HB includes a physical layer circuit PHY and a link controller LKC. The physical layer circuit PHY is a circuit for transferring data through a serial bus using differential signals. Specifically, first and second signals DP and DM forming small-amplitude differential signals (differential data signals) and first and second signals CKP and CKM forming differential signals (differential clock signals) are input to the physical layer circuit PHY. The physical layer circuit PHY differentially amplifies the signals DP and DM and the signals CKP and CKM to receive data from a host (host processor). The link controller LKC performs a link layer process. Specifically, the link controller LKC analyzes a packet received using the differential signals, for example.

When incorporating the high-speed I/F circuit block HB which implements a high-speed serial transfer in the integrated circuit device, the chip area increases by the area of the high-speed I/F circuit block HB. Moreover, high-speed serial interface pads PDP, PDM, PCKP, and PCKM are required in addition to the MPU interface pads PD23 to PD0, PXWR, PXRD, PA0, and PXCS. Therefore, when the display panel 300 shown in FIG. 1 is an MPU interface (parallel interface) panel, the panel manufacturer must newly design a high-speed serial interface display panel in order to implement a high-speed serial transfer. This hinders widespread use of a high-speed serial interface.

On the other hand, the IC manufacturer must design and develop an integrated circuit device model provided with an MPU interface and an integrated circuit device model provided with a high-speed serial interface in order to satisfy a wide range of demands from panel manufacturers. This increases the development cost and complicates the product management.

In order to deal with this problem, this embodiment employs a method of using a single pad as a parallel interface pad and a serial interface pad.

As shown in FIG. 2, the integrated circuit device includes the data pads PD23 to PD0, for example. The integrated circuit device also includes the MPU interface control pads PXWR, PXRD, PA0, and PXCS. The integrated circuit device also includes I/O circuits (I/O cells) C23 to C0 respectively receiving complementary metal oxide semiconductor (CMOS) level data signals from the data pads PD23 to PD0. Likewise, the integrated circuit device includes control pad I/O circuits C24 to C27 respectively receiving CMOS level signals (signals having an amplitude larger than that of the differential signal; e.g., signals having an amplitude of 1.2 V to 5 V) from the control pads PXWR, PXRD, PA0, and PXCS. The term “I/O circuit” refers to an input/output buffer, an input buffer, or an output buffer.

The high-speed I/F circuit block HB includes the physical layer circuit PHY, and transfers data through the serial bus using the differential signals. The logic circuit block LB receives signals from the high-speed I/F circuit block HB and the I/O circuits C27 to C0.

In this embodiment, at least some of the data pads PD23 to PD0 shown in FIG. 2 are set to be shared pads. The signals DP and DM and the signals CKP and CKM forming the differential signals are input to the physical layer circuit PHY through the shared pads.

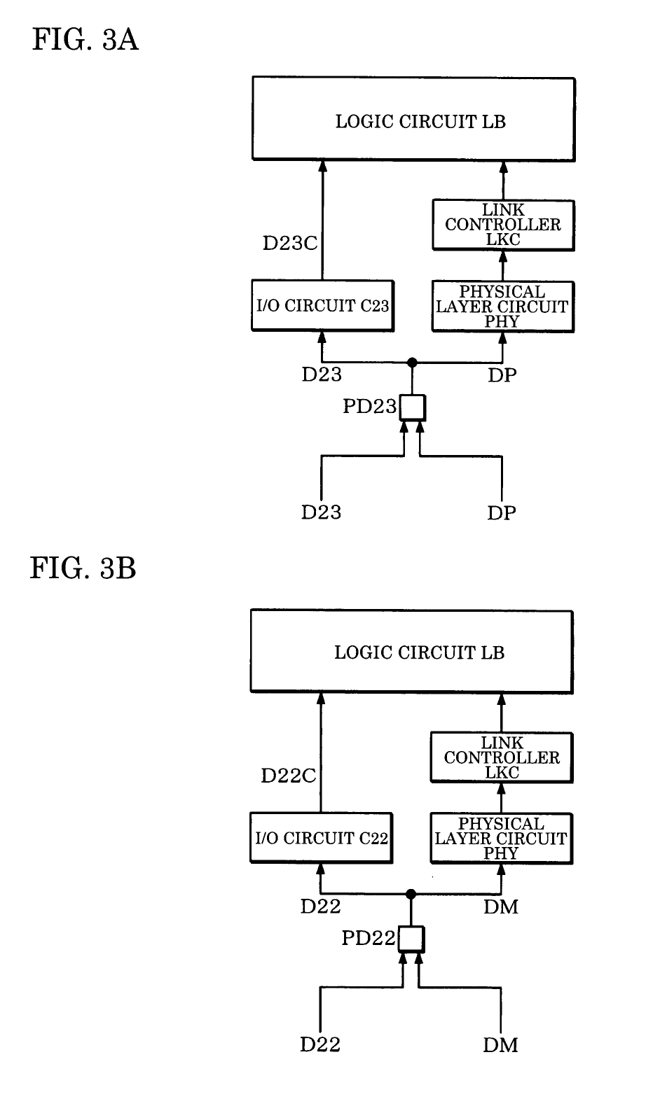

In FIG. 3A, the data pad PD23 is set to be a shared pad. The I/O circuit C23 receives a CMOS level (digital signal level) data signal D23 through the shared pad PD23, and buffers the data signal D23. The buffered data signal D23C is output to the logic circuit block LB.

The physical layer circuit PHY receives the first signal DP forming the differential signals through the shared pad PD23.

In FIG. 3B, the data pad PD22 is set to be a shared pad. The I/O circuit C22 receives the CMOS level data signal D22 through the shared pad PD22, and buffers the data signal D22. The buffered data signal D22C is output to the logic circuit block LB.

The physical layer circuit PHY receives the second signal DM forming the differential signals through the shared pad PD22.

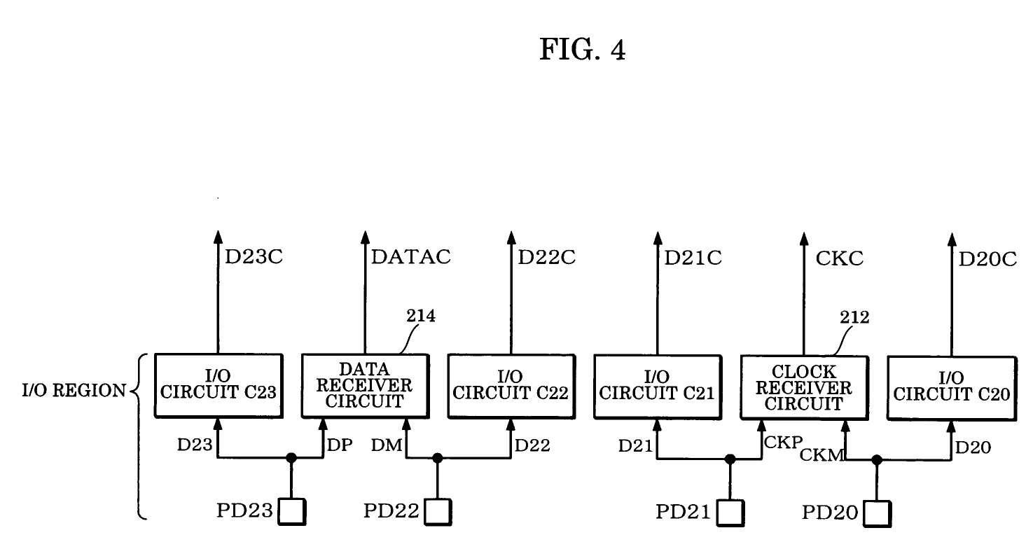

FIG. 4 shows an example of the layout of the I/O circuits and the physical layer circuit. In FIG. 4, the physical layer circuit includes a data receiver circuit 214 (receiver circuit in a broad sense) to which the first and second signals DP and DM of the differential signals (differential data signals) are input. The physical layer circuit also includes a clock receiver circuit 212 (receiver circuit in a broad sense) to which the first and second signals CKP and CKM of the differential signals (differential clock signals) are input. At least the data receiver circuit 214 and the clock receiver circuit 212 of the physical layer circuit are disposed in an I/O region in which the I/O circuits C23 to C20 and the like are disposed. Specifically, the high-speed serial transfer receiver circuits 214 and 212 are disposed in the region in which the I/O circuits are originally disposed.

In FIG. 4, the I/O circuit C23 (first I/O circuit) to which the CMOS level data signal D23 is input from the shared pad PD23 (first shared pad) is disposed in the I/O region. The I/O circuit C22 (second I/O circuit) to which the CMOS level data signal D22 is input from the shared pad PD22 (second shared pad) is disposed in the I/O region. The I/O circuits C22 and C23 buffer the data signals D23 and D22 and output the data signals D23C and D22C, respectively.

The data receiver circuit 214 receives a signal input from the shared pad PD23 as the first signal DP of the differential signals, and receives a signal input from the shared pad PD22 as the second signal DM of the differential signals. The data receiver circuit 214 differentially amplifies the signals DP and DM, and outputs the resulting signal DATAC.

In FIG. 4, the I/O circuit C21 (first I/O circuit) to which the CMOS level data signal D21 is input from the shared pad PD21 (first shared pad) is disposed in the I/O region. The I/O circuit C20 (second I/O circuit) to which the CMOS level data signal D20 is input from the shared pad PD20 (second shared pad) is disposed in the I/O region. The I/O circuits C21 and C20 buffer the data signals D21 and D20 and output the data signals D21C and D20C, respectively.

The clock receiver circuit 212 receives a signal input from the shared pad PD21 as the first signal CKP of the differential signals, and receives a signal input from the shared pad PD20 as the second signal CKM of the differential signals. The clock receiver circuit 212 differentially amplifies the signals CKP and CKM and outputs the resulting clock signal CKC.

In FIG. 4, the data receiver circuit 214 is disposed between the first I/O circuit C23 and the second I/O circuit C22. Likewise, the data receiver circuit 212 is disposed between the first I/O circuit C21 and the second I/O circuit C20.

According to the layout shown in FIG. 4, since the receiver circuits 214 and 212 can be disposed while effectively utilizing the I/O region, the layout efficiency can be increased.

In FIG. 4, the I/O circuits C23 and C22 are disposed axisymmetrically with respect to the receiver circuit 214. Therefore, the lines of the signals DP and DM can be prevented from intersecting the lines of the signals D23 and D22, whereby the signals DP and DM from the shared pads PD23 and PD22 can be input to the receiver circuit 214 along a short path. This prevents a situation in which noise from the signals D23 and D22 is superimposed on the lines of the signals DP and DM, whereby a transfer error and the like can be prevented.

In FIG. 4, the I/O circuits C21 and C20 are disposed axisymmetrically with respect to the receiver circuit 212. Therefore, the lines of the signals CKP and CKM can be prevented from intersecting the lines of the signals D21 and D20, whereby the signals CKP and CKM from the shared pads PD21 and PD20 can be input to the receiver circuit 212 along a short path. This prevents a situation in which noise from the signals D21 and D20 is superimposed on the lines of the signals CKP and CKM, whereby a transfer error and the like can be prevented.

For example, a digital signal with a CMOS level amplitude is input to an MPU interface data pad. On the other hand, a small-amplitude differential signal is input to a high-speed serial interface differential input pad. Therefore, since a transfer error and the like may occur during high-speed serial transfer when noise from the digital signal is superimposed on the differential signal, it has been common technical knowledge to separately provide the data pad and the differential input pad. This embodiment is characterized in that the data pad is also used as the differential input pad contrary to the common technical knowledge. This pad sharing method has the following advantages.

First, an MPU interface display panel and a high-speed serial interface display panel can be made glass-compatible. Specifically, when the MPU interface data pad and the differential input pad are separately provided on the integrated circuit device, a display panel designed and developed for the MPU interface cannot be used as a display panel (array substrate or glass substrate) on which the integrated circuit device is mounted. Therefore, the panel manufacturer must newly design and develop a high-speed serial interface display panel, thereby making it difficult to prompt the panel manufacturer to switch to the high-speed serial interface.

According to this embodiment, since the MPU interface data pad is also used as the differential input pad, a display panel designed and developed for the MPU interface can be used as a high-speed serial interface display panel. This makes it possible to prompt the panel manufacturer to switch to the high-speed serial interface, whereby the spread of the high-speed serial transfer can be attempted.

Second, since the number of models, the design and development period, and the chip area of the integrated circuit device can be reduced, the cost of the integrated circuit device can be reduced. Specifically, when the pad sharing method according to this embodiment is not employed, it is necessary to separately design and develop a model provided with the MPU interface and a model provided with the high-speed serial interface, whereby the number of models and the design and development period of the integrated circuit device are increased.

According to this embodiment, one model designed and developed so that the data pad is also used as the differential input pad can be supplied to the panel manufacturer as an integrated circuit device provided with only the MPU interface and an integrated circuit device provided with the high-speed serial interface. Specifically, one model can be marketed as an MPU interface model and a high-speed serial interface model utilizing a signal switching method and a mask switching method described later. Therefore, the number of models to be designed and developed and the design and development period of the integrated circuit device can be reduced, whereby the cost of the integrated circuit device can be reduced.

When the data pad is also used as the differential input pad, a situation may occur in which noise of the digital signal input to the shared pad is superimposed on the differential signal. According to this embodiment, such a situation is prevented by contriving the layout method and the like as shown in FIG. 4.

3. I/O Circuit and High-Speed I/F Circuit

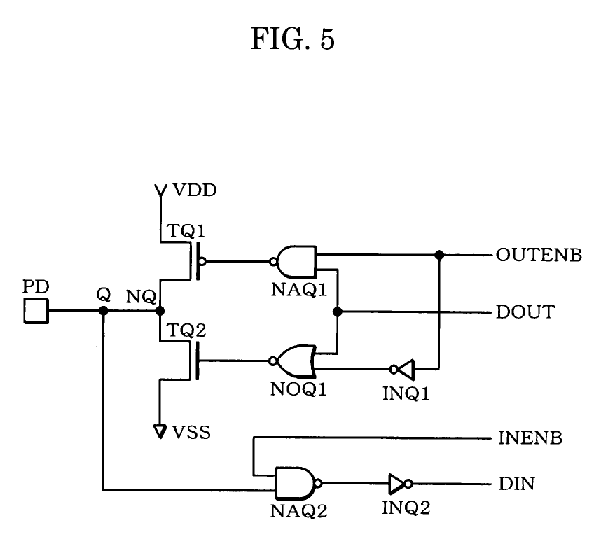

FIG. 5 shows a configuration example of the I/O circuit. FIG. 5 shows an example of the I/O circuit having an input-output buffer. A P-type transistor TQ1 and an N-type transistor TQ2 provided in series between power supplies VDD and VSS form an output buffer. The outputs of a NAND circuit NAQ1 and a NOR circuit NOQ1 are respectively connected with the gates of the transistors TQ1 and TQ2. Signals DOUT and OUTENB are input to the NAND circuit NAQ1. Inversion signals of the signals DOUT and OUTENB are input to the NOR circuit NOQ1. The output buffer formed by the transistors TQ1 and TQ2 outputs a voltage corresponding to the signal DOUT to a node NQ.

A NAND circuit NAQ2 and an inverter circuit INQ2 form an input buffer. A signal Q of the node NQ of a data pad PD and a signal INENB are input to the NAND circuit NAQ2.

When using the I/O circuit shown in FIG. 5 as the output buffer, the signal OUTENB is set at the H level (active). This causes the signal Q corresponding to the signal DOUT to be output from the data pad PD. When using the I/O circuit as the input buffer, the signal INENB is set at the H level. This causes the signal Q from the pad PD to be buffered and input as a signal DIN. Although FIG. 5 shows an example in which the I/O circuit is the input-output buffer, the I/O circuit may be an input buffer or the like.

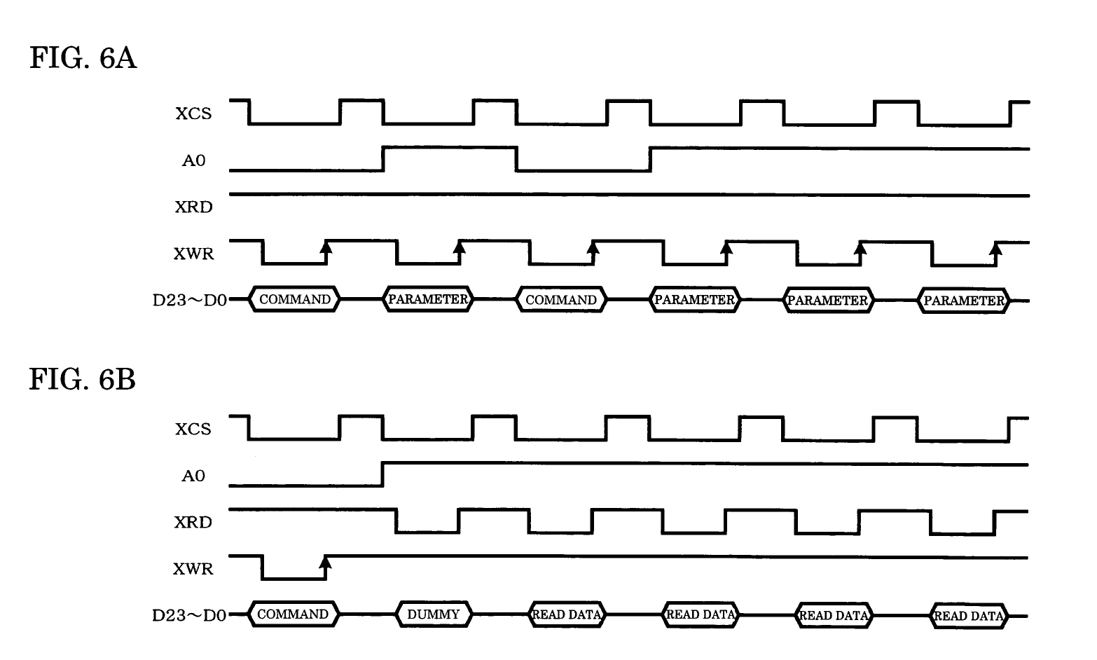

FIGS. 6A and 6B show MPU interface signal waveform examples. FIG. 6A shows a write waveform example, and FIG. 6B shows a read waveform example.

In FIG. 6A, a portion in which the L level of the signal XCS overlaps the L level of the signal XWR is a write signal. When the signal A0 which is a data/command identification signal is set at the L level, a command is written based on the signal XWR through the data bus of the data D23 to D0. When the signal A0 is set at the H level, a parameter is written based on the signal XWR through the data bus of the data D23 to D0. The data bus of the data D23 to D0 may be set at an arbitrary bus width.

In FIG. 6B, a portion in which the L level of the signal XCS overlaps the L level of the signal XRD is a read signal. When the signal A0 is set at the L level, a command is read based on the signal XRD through the data bus of the data D23 to D0. When the signal A0 is set at the H level, data (and dummy data) is read based on the signal XRD through the data bus of the data D23 to D0. The MPU interface signal waveform is not limited to FIGS. 6A and 6B. An MPU interface signal waveform differing from FIGS. 6A and 6B may also be employed.

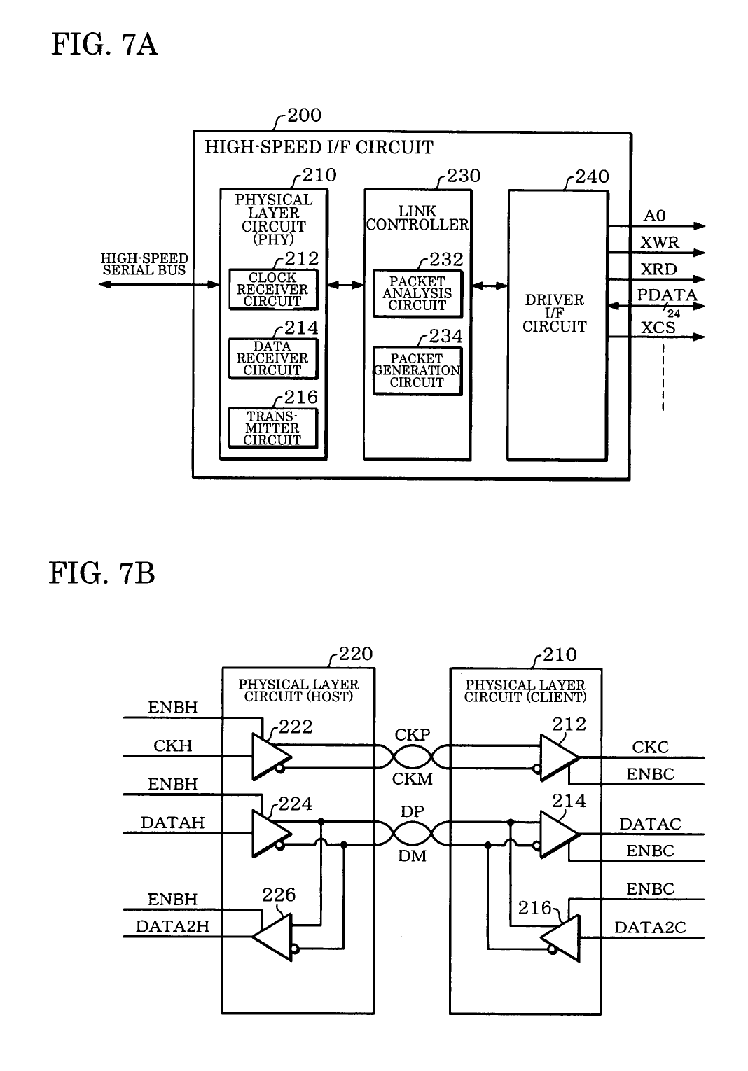

FIG. 7A shows a detailed circuit configuration example of a high-speed I/F circuit 200. The high-speed I/F circuit 200 includes a physical layer circuit 210, a link controller 230, and a driver I/F circuit 240.

The physical layer circuit 210 (transceiver) is a circuit for receiving or transmitting data (packet) and a clock signal using differential signals (differential data signals and differential clock signals). Specifically, the physical layer circuit 210 transmits or receives data and the like by current-driving or voltage-driving differential signal lines of a serial bus. The physical layer circuit 210 may include a clock receiver circuit 212, a data receiver circuit 214, a transmitter circuit 216, and the like.

The link controller 230 performs a process of a link layer (or transaction layer) higher than the physical layer. Specifically, the link controller 230 may include a packet analysis circuit 232. When the physical layer circuit 210 has received a packet from a host (host device) through the serial bus, the packet analysis circuit 232 analyzes the received packet. Specifically, the packet analysis circuit 232 separates the header and data of the received packet and extracts the header. The link controller 230 may include a packet generation circuit 234. The packet generation circuit 234 generates a packet when transmitting a packet to the host through the serial bus. Specifically, the packet generation circuit 234 generates the header of the packet to be transmitted, and assembles the packet by combining the header and data. The packet generation circuit 234 directs the physical layer circuit 210 to transmit the generated packet.

The driver I/F circuit 240 performs an interface process between the high-speed I/F circuit 200 and an internal circuit of a display driver. Specifically, the driver I/F circuit 240 generates host interface signals including the address 0 signal A0, the write signal XWR, the read signal XRD, a parallel data signal PDATA, the chip select signal XCS, and the like, and outputs the generated signals to the internal circuit (host interface circuit 46) of the display driver.

In FIG. 7B, a physical layer circuit 220 is provided in the host device, and the physical layer circuit 210 is provided in the display driver. Reference numerals 212, 214, and 226 indicate receiver circuits, and reference numerals 216, 222, and 224 indicate transmitter circuits. The operations of the receiver circuits 212, 214, and 226 and the transmitter circuits 216, 222, and 224 are enabled or disabled using enable signals ENBH and ENBC.

The host-side clock transmitter circuit 222 outputs the differential clock signals CKP and CKM. The client-side clock receiver circuit 212 differentially amplifies the differential clock signals CKP and CKM, and outputs the resulting clock signal CKC to the circuit in the subsequent stage.

The host-side data transmitter circuit 224 outputs the differential data signals DP and DM. The client-side data receiver circuit 214 differentially amplifies the differential data signals DP and DM, and outputs the resulting data DATAC to the circuit in the subsequent stage. In FIG. 7B, data can be transferred from the client to the host using the client-side data transmitter circuit 216 and the host-side data receiver circuit 226.

The configuration of the physical layer circuit 210 is not limited to FIGS. 7A and 7B. Various modifications may be made. For example, the physical layer circuit 210 may include a serial/parallel conversion circuit, a parallel/serial conversion circuit, and the like (not shown). The physical layer circuit 210 may include a phase locked loop (PLL) circuit, a bias voltage generation circuit, and the like. The differential signal lines of the serial bus may have a multi-channel configuration. The physical layer circuit 210 includes at least one of the receiver circuit and the transmitter circuit. For example, the physical layer circuit 210 may not include the transmitter circuit. A sampling clock signal may be generated based on the received data without providing the clock receiver circuit.

4. Shared Pad Switching Method

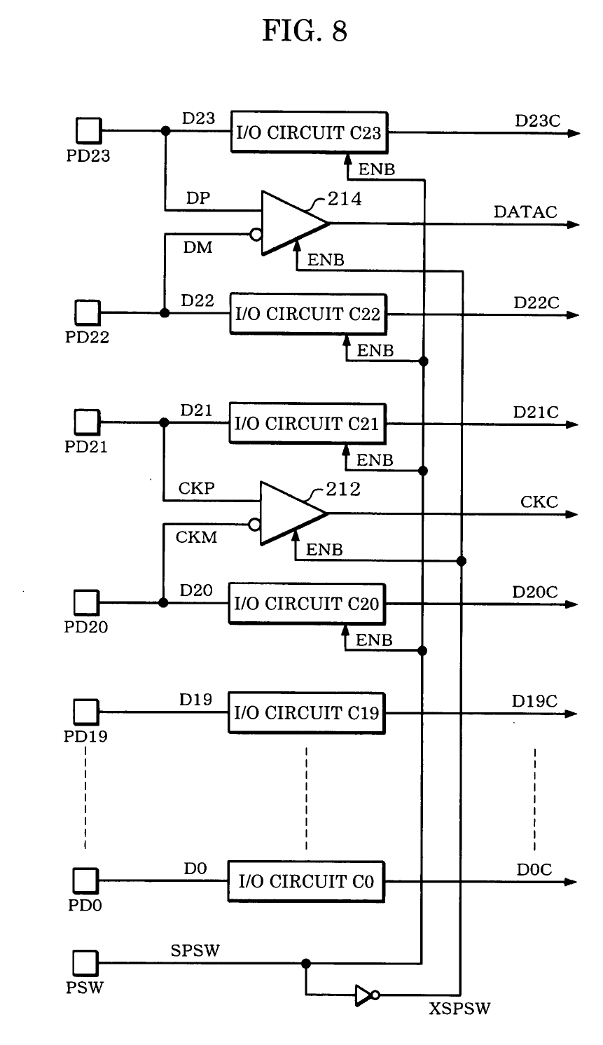

A shared pad switching method according to this embodiment is classified as a signal switching method and a mask switching method. FIG. 8 shows an example of the signal switching method.

In FIG. 8, the shared pads PD23 and PD22 are connected with the I/O circuits C23 and C22 and the receiver circuit 214 of the physical layer circuit. Specifically, the shared pads PD23 and PD22 are connected with the DP and DM input terminals of the data receiver circuit 214. The shared pads PD21 and PD20 are connected with the I/O circuits C21 and C20 and the receiver circuit 212 of the physical layer circuit. Specifically, the shared pads PD21 and PD20 are connected with the CKP and CKM input terminals of the clock receiver circuit 212. The normal data pads PD19 to PD0 other than the shared pads PD23 to PD20 are connected with the I/O circuits C19 to C0.

The receiver circuit 214 is disabled in an MPU interface mode in which the shared pads PD23 and PD22 are used as the input pads of the CMOS level data signals D23 and D22. The I/O circuits C23 and C22 are enabled. The I/O circuits C23 and C22 are disabled in a serial interface mode in which the shared pads PD23 and PD22 are used as the input pads of the signals DP and DM. The receiver circuit 214 is enabled.

The receiver circuit 212 is disabled in the MPU interface mode in which the shared pads PD21 and PD20 are used as the input pads of the CMOS level data signals D21 and D20. The I/O circuits C21 and C20 are enabled. The I/O circuits C21 and C20 are disabled in the serial interface mode in which the shared pads PD21 and PD20 are used as the input pads of the signals CKP and CKM. The receiver circuit 212 is enabled.

In FIG. 8, a pad PSW is provided which serves as a switching terminal for switching the MPU interface mode and the serial interface mode. When a switching signal SPSW input through the pad PSW is set at the H level, the integrated circuit device is set in the MPU interface mode. Specifically, the receiver circuits 214 and 212 are disabled, and the I/O circuits C23 to C20 are enabled. This causes the data signals D23 to D20 input through the shared pads PD23 to PD20 to be buffered by the I/O circuits C23 to C20 and input to the logic circuit block.

When the switching signal SPSW is set at the L level, the integrated circuit device is set in the serial interface mode. Specifically, the I/O circuits C23 to C20 are disabled, and the receiver circuits 214 and 212 are enabled. This causes the signals DP and DM input through the shared pads PD23 and PD22 to be differentially amplified by the receiver circuit 214 and the signals CKP and CKM input through the shared pads PD21 and PD20 to be differentially amplified by the receiver circuit 212, whereby a high-speed serial transfer is realized.

The I/O circuits C23 to C20 may be disabled or enabled using the signals OUTENB and INENB shown in FIG. 5, for example. The receiver circuits 214 and 212 may be disabled or enabled by turning OFF/ON the current paths of the receiver circuits 214 and 212, for example.

According to the signal switching method shown in FIG. 8, the MPU interface mode and the serial interface mode of the integrated circuit device can be switched merely by externally controlling the switching signal SPSW, whereby the shared pads PD23 to PD20 can be used for MPU interface or serial interface. This enables the shared pads to be switched using a simple process, whereby convenience can be increased. The MPU interface mode and the serial interface mode may be switched by a register setting or the like instead of using the switching signal SPSW.

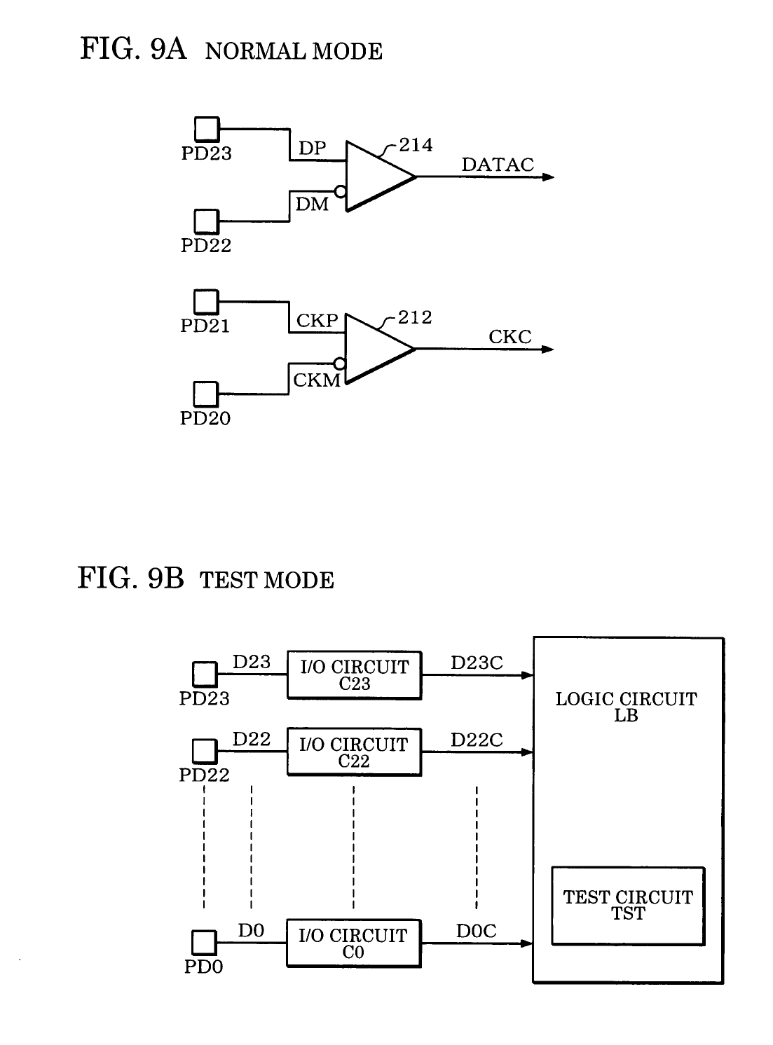

A test process when using the method shown in FIG. 8 is described below with reference to FIGS. 9A and 9B. For example, the switching signal SPSW is set at the L level in a normal mode, whereby the integrated circuit device is set in the serial interface mode, as shown in FIG. 9A. In the serial interface mode, data must be input using the differential signals. Therefore, it is difficult to test the integrated circuit device in the serial interface mode using test signals from an external tester by setting the integrated circuit device in a test mode.

In FIG. 9B, even if the integrated circuit device is set in the serial interface mode in the normal mode, the integrated circuit device is set in the MPU interface mode in the test mode. The logic circuit block LB provided in the subsequent stage of the I/O circuits C23 to C0 performs a test process in the test mode based on CMOS level test signals input from a tester through the data pads PD23 to PD0 and the I/O circuits C23 to C0. Specifically, a test circuit TST provided in the logic circuit block LB performs the test process based on the test signals.

This enables the test process to be performed in the test mode based on the CMOS level parallel test signals, whereby the test efficiency can be increased. Specifically, a high-speed serial transfer is performed in the normal mode using the differential signals, and the integrated circuit device can be tested in the test mode using the CMOS level signals which can be easily handled by the tester. Therefore, a high-speed serial transfer and an increase in test efficiency can be achieved in combination.

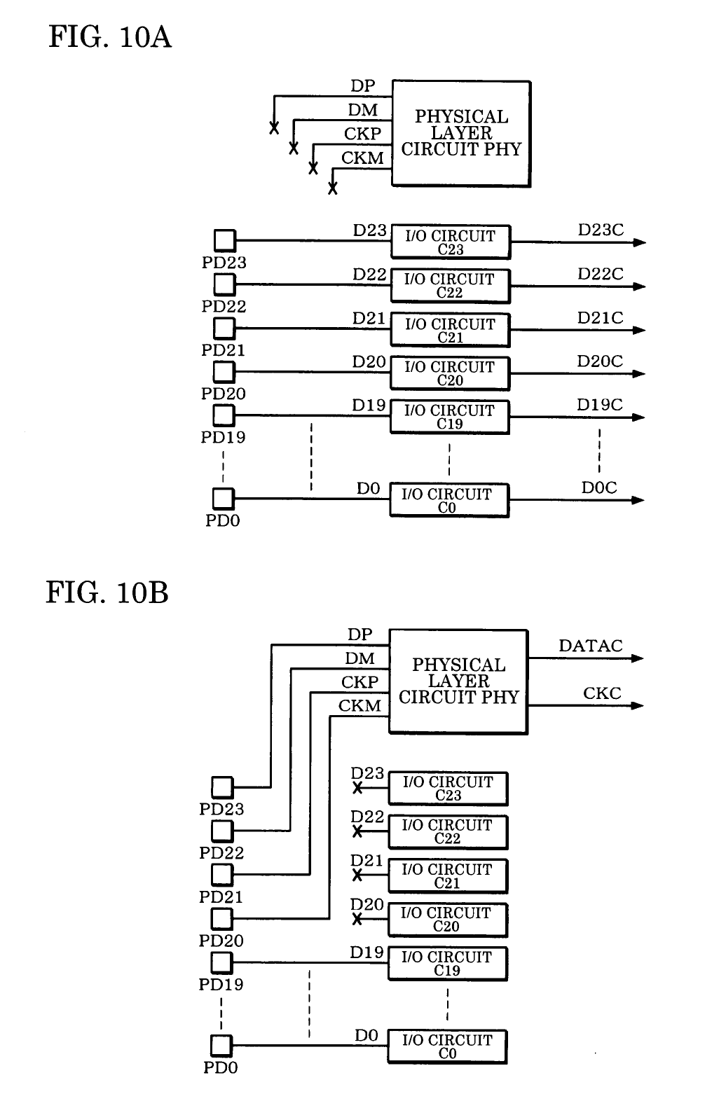

FIGS. 10A and 10B are views showing an example of the mask switching method. In this method, the shared pads are switched by changing an interconnect mask.

As shown in FIG. 10A, when the shared pads PD23 to PD20 are used as the input pads of the CMOS level data signals, the shared pads PD23 to PD20 and the I/O circuits C23 to C20 are connected via interconnects. Specifically, the interconnects (metal interconnects) are formed using a mask having an interconnect pattern in which the shared pads PD23 to PD20 are not connected with the physical layer circuit PHY, but are connected with the I/O circuits C23 to C20. In FIG. 10A, only a bulk portion (e.g., active region and poly-interconnect) may be formed for the physical layer circuit PHY (high-speed I/F circuit), and an interconnect layer may not be formed for the physical layer circuit PHY. Alternatively, the physical layer circuit PHY may be partially used for the I/O circuits C23 to C20.

As shown in FIG. 10B, when the shared pads PD23 to PD20 are used as the input pads of the signals DP, DM, CKP, and CKM, the shared pads PD23 to PD20 and the physical layer circuit are connected via interconnects. Specifically, the interconnects (metal interconnects) are formed using a mask having an interconnect pattern in which the shared pads PD23 to PD20 are not connected with the I/O circuits C23 to C20, but are connected with the physical layer circuit PHY. In FIG. 10B, only a bulk portion may be formed for the I/O circuits C23 to C20, and an interconnect layer may not be formed for the I/O circuits C23 to C20. Alternatively, the I/O circuits C23 to C20 may be partially used for the physical layer circuit PHY.

The method shown in FIGS. 10A and 10B has an advantage in that the shared pads are switched merely by changing the interconnects by changing the mask, without additionally providing the input terminal of the switching signal SPSW shown in FIG. 8.

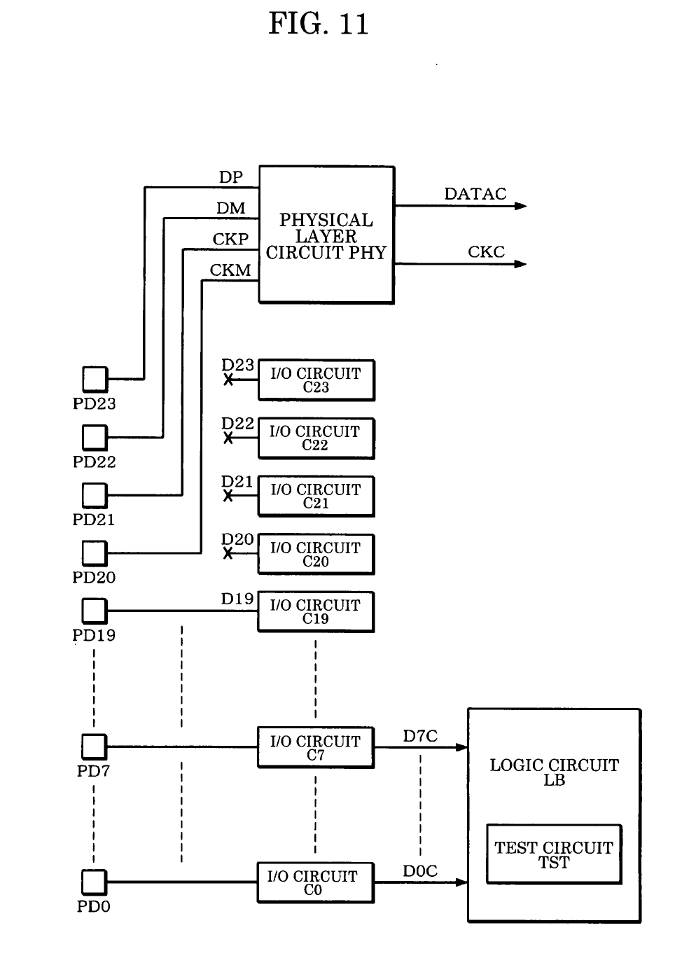

A test process when using the method shown in FIGS. 10A and 10B is described below with reference to FIG. 11. For example, the integrated circuit device is set in the test mode when the shared pads PD23 to PD20 and the physical layer circuit PHY are connected via the interconnects using the mask, as shown in FIG. 11. In the serial interface mode, data must be input using the differential signals. Therefore, it is difficult to test the integrated circuit device in the serial interface mode using test signals from an external tester by setting the integrated circuit device in the test mode.

In FIG. 11, the logic circuit block LB performs a test process based on CMOS level test signals input through the I/O circuits C7 to C0 from the pads PD7 to PD0 among the data pads PD23 to PD0 other than the shared pads PD23 to PD20. Specifically, the test circuit TST provided in the logic circuit block LB performs the test process based on the test signals.

According to this configuration, a data transfer in the normal mode is realized by a high-speed serial transfer using the physical layer circuit PHY, and the integrated circuit device can be tested in the test mode using the CMOS level parallel signals which can be easily handled by the tester. Therefore, a high-speed serial transfer and an increase in test efficiency can be achieved in combination.

In FIG. 11, the test process is performed using the 8-bit test signal. The bit width of the test signal is arbitrary. For example, the test signal may have a 16-bit width. In FIGS. 8 to 11, the data pads PD23 to PD0 are set to be shared pads. Note that the data pads set to be shared pads are not limited thereto. For example, lower-order-bit data pads may be set to be shared pads. The number of data pads set to be shared pads may be smaller than four (e.g., two DP and DM pads), or may be five or more.

5. Subdisplay Panel

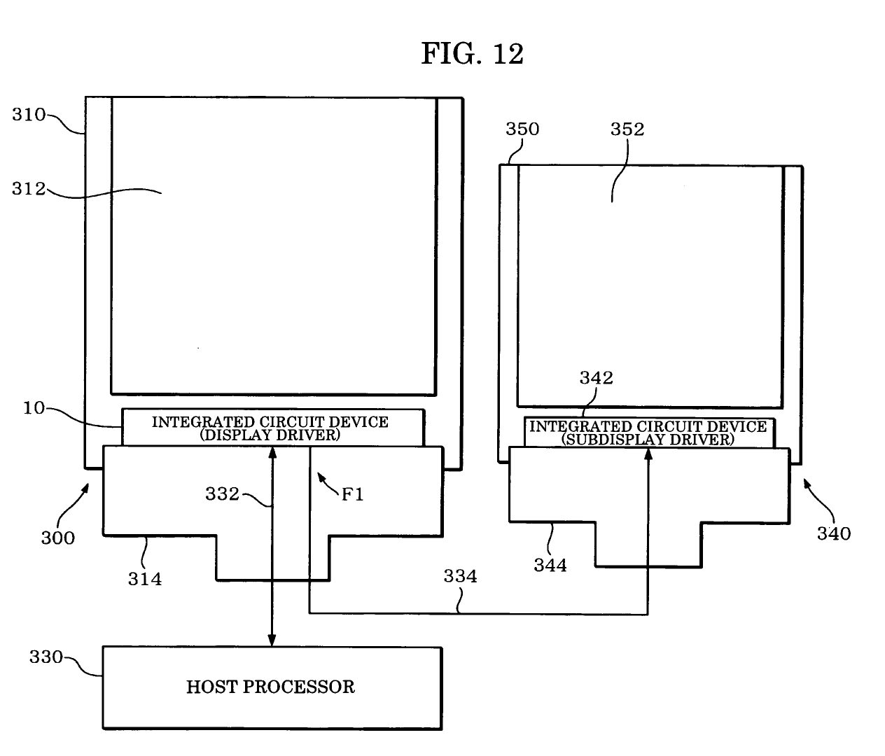

In FIG. 12, the display operation of a subdisplay panel 340 is performed in addition to the display panel 300 (main display panel) based on data transferred from the host processor 330. Specifically, the integrated circuit device 10 according to this embodiment includes at least one data driver block for driving the data lines of the display panel 300, whereby the display operation of the display panel 300 is performed. The integrated circuit device 10 receives data from the host processor 330 through a high-speed serial bus 332 (or MPU interface bus), and transfers the received data to an integrated circuit device 342 of the subdisplay panel 340 (subdisplay driver) through a CMOS level bus 334 (at least one of parallel bus and serial bus), for example. The integrated circuit device 342 includes a data driver block for driving data lines of the subdisplay panel 340 and the like, and drives the subdisplay panel 340.

The subdisplay panel 340 is a panel of which the size is smaller (panel of which the number of display pixels is smaller) than that of the display panel 300, for example. The display panel 300 may be formed using an active matrix type panel utilizing a switching element (two-terminal nonlinear element) such as a thin film transistor (TFT) or a thin film diode (TFD), for example. The subdisplay panel 340 may be formed using a simple matrix type panel utilizing an STN liquid crystal or the like, or may be formed using an active matrix type panel. The subdisplay panel 340 may include an array substrate 350 on which an array section 352 (display section) is formed, and a common substrate (not shown). The display panel 300 and the subdisplay panel 340 may be panels (e.g., organic EL panel) other than the liquid crystal panel.

The integrated circuit device 10 may include a subdisplay panel interface circuit (not shown), for example. When a packet received from the host processor 330 (host device) includes a command or data for the subdisplay panel (subdisplay driver), the subdisplay panel interface circuit outputs the command or data to the integrated circuit device 342 (subdisplay driver) through the bus 334 of which the speed is lower than the high-speed serial bus 332. This enables not only the display panel 300 but also the subdisplay panel 340 to be controlled.

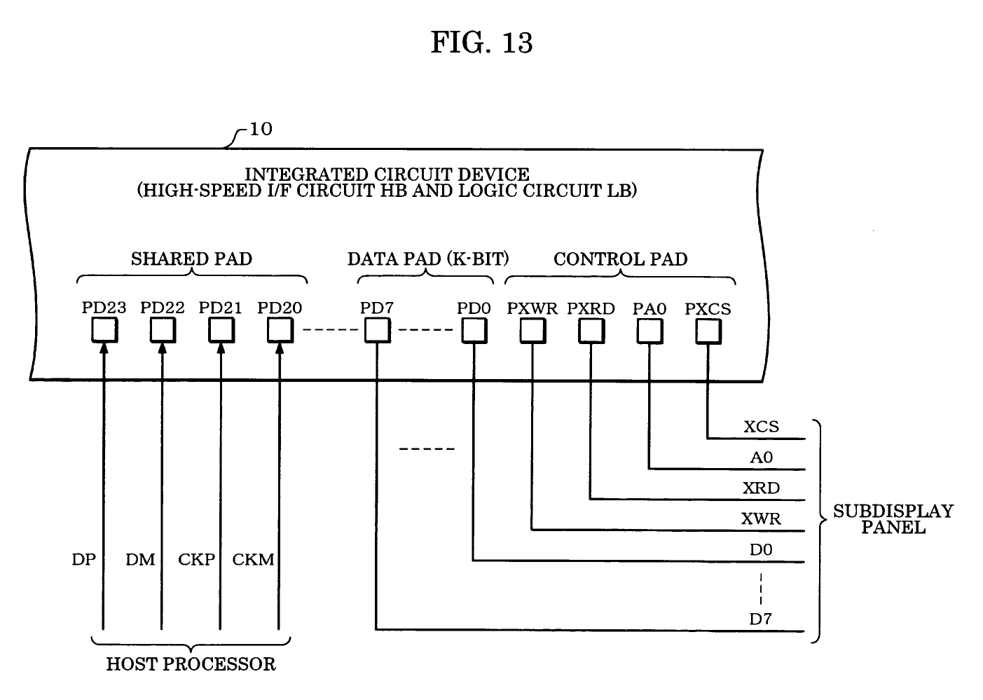

FIG. 13 is a detailed interconnection diagram of the portion indicated by F1 in FIG. 12. The pads PD23 to PD20 are shared pads, and the pads PD7 to PD0 are k-bit (k is a positive integer) data pads other than the shared pads. In FIG. 13, k=8. The pads PXWR, PXRD, PA0, and PXCS are control pads. In the MPU interface mode, these control pads serve as the input pads of the MPU interface control signals XWR, XRD, A0, and XCS described with reference to FIGS. 6A and 6B. When transferring data received from the host processor to the subdisplay panel, these control pads serve as the output pads of the control signals XWR, XRD, A0, and XCS for transferring data to the subdisplay panel. In this case, parallel data is output to the subdisplay panel through the 8-bit (k-bit) data pads PD7 to PD0. Note that data may be transferred to the subdisplay panel using CMOS level serial signals.

In FIG. 13, the logic circuit block LB (subpanel interface circuit) of the integrated circuit device 10 receives data (DP and DM) received by the high-speed I/F circuit HB through the high-speed serial bus. The logic circuit block LB outputs the data signals D7 to D0 for driving the subdisplay panel to the subdisplay panel (integrated circuit device 342) through the k-bit (k=8) data pads PD7 to PD0 among the data pads. The logic circuit block LB outputs the control signals XWR, XRD, A0, and XCS for transferring data through the data pads PD7 to PD0 to the subdisplay panel through the control pads PXWR, PXRD, PA0, and PXCS. The logic circuit block LB performs an MPU interface (parallel interface) data transfer using the data signals D7 to D0 and the control signals XWR, XRD, A0, and XCS. This enables the data received from the host processor utilizing a high-speed serial transfer to be transferred to the subdisplay panel.

In FIG. 13, the k-bit data pads PD7 to PD0 are disposed between the shared pads PD23 to PD20 and the control pads PXWR, PXRD, PA0, and PXCS. This prevents noise from being superimposed on the high-speed serial transfer differential signals while enabling data received via high-speed serial transfer to be transferred to the subdisplay panel.

Specifically, if the lower-order-bit data pads PD7 to PD0 are set to be shared pads and the higher-order-bit data pads PD23 to PD16 are set to be subdisplay panel data pads, the differential signal line from the host processor intersects the data signal line connected to the subdisplay panel. As a result, noise on the data signal line connected to the subdisplay panel is superimposed on the differential signal line, whereby an error or the like occurs during high-speed serial transfer.

In FIG. 13, since the higher-order-bit data pads PD23 to PD20 are set to be shared pads and the lower-order-bit data pads PD7 to PD0 are set to be subdisplay panel data pads, the differential signal line does not intersect the data signal line connected to the subdisplay panel, whereby an error or the like which occurs during high-speed serial transfer due to noise can be prevented.

6. Detailed Layout of Integrated Circuit Device

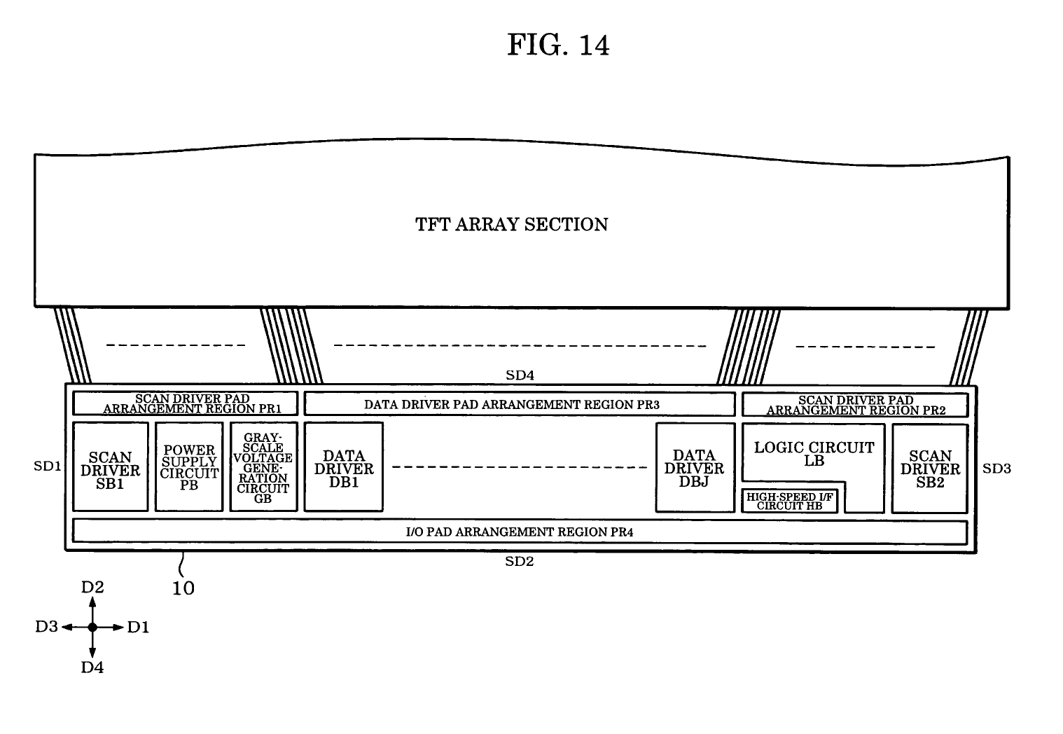

FIG. 14 shows a detailed layout example of the integrated circuit device 10. In FIG. 14, the direction from a first side SD1 (short side) of the integrated circuit device 10 toward a third side SD3 opposite to the first side SD1 is defined as a first direction D1, and the direction opposite to the first direction D1 is defined as a third direction D3. The direction from a second side SD2 (long side) of the integrated circuit device 10 toward a fourth side SD4 opposite to the second side SD2 is defined as a second direction D2, and the direction opposite to the second direction D2 is defined as a fourth direction D4. In FIG. 14, the left side of the integrated circuit device 10 is defined as the first side SD1, and the right side of the integrated circuit device 10 is defined as the third side SD3. Note that the left side may be defined as the third side SD3, and the right side may be defined as the first side SD1.

The integrated circuit device 10 shown in FIG. 14 includes data driver blocks DB1 to DBJ for driving the data lines disposed along the direction D1, and first and second scan driver blocks SB1 and SB2 for driving the scan lines. The integrated circuit device 10 also includes a grayscale voltage generation circuit block GB for generating grayscale voltages, a power supply circuit block PB for generating a power supply voltage, the high-speed I/F circuit block HB, and the logic circuit block LB.

The logic circuit block LB receives data received by the high-speed I/F circuit block HB. The logic circuit block LB transfers grayscale adjustment data for adjusting the grayscale voltage to the grayscale voltage generation circuit block GB, and transfers power supply adjustment data for adjusting the power supply voltage to the power supply circuit block PB.

In FIG. 14, the grayscale voltage generation circuit block GB is disposed in the direction D3 of the data driver blocks DB1 to DBJ. Specifically, the grayscale voltage generation circuit block GB is disposed in the direction D3 of the leftmost data driver block DB1. Likewise, the power supply circuit block PB is disposed in the direction D3 of the data driver blocks DB1 to DBJ. Specifically, the power supply circuit block PB is disposed in the direction D3 of the leftmost data driver block DB1. The high-speed I/F circuit block HB and the logic circuit block LB are disposed in the direction D1 of the data driver blocks DB1 to DBJ. Specifically, the high-speed I/F circuit block HB and the logic circuit block LB are disposed in the direction D1 of the rightmost data driver block DBJ.

The grayscale voltage generation circuit block GB is disposed between the first scan driver block SB1 and the data driver blocks DB1 to DBJ. The high-speed I/F circuit block HB is disposed between the second scan driver block SB2 and the data driver blocks DB1 to DBJ.

In FIG. 14, a local line formed of a lower interconnect layer is provided between the adjacent circuit blocks. A global line formed of an interconnect layer positioned in an upper layer of the local line is provided between the nonadjacent circuit blocks along the direction D1. A grayscale global line for supplying the grayscale voltage from the grayscale voltage generation circuit block GB to the data driver blocks DB1 to DBJ and a power supply global line for supplying the power supply voltage from the power supply circuit block PB are provided over the data driver blocks DB1 to DBJ along the direction D1.

When disposing the scan driver blocks SB1 and SB2 on either end of the integrated circuit device 10, as shown in FIG. 14, it is preferable that scan driver pads through which scan signals are output be disposed on either end of the integrated circuit device 10 taking the wiring efficiency into consideration. On the other hand, the data driver blocks DB1 to DBJ are disposed near the center of the integrated circuit device 10. Therefore, it is preferable that data driver pads through which data signals are output be disposed near the center of the integrated circuit device 10 taking the wiring efficiency into consideration.

In FIG. 14, scan driver pad arrangement regions PR1 and PR2 are provided on either end of the integrated circuit device 10, and a data driver pad arrangement region PR3 is provided between the scan driver pad arrangement regions PR1 and PR2. This ensures that output lines of the scan driver blocks SB1 and SB2 and output lines of the data driver blocks DB1 to DBJ can be efficiently connected with the pads of the scan driver pad arrangement regions PR1 and PR2 and the pads of the data driver pad arrangement region PR3.

In FIG. 14, the data driver blocks DB1 to DBJ are disposed near the center of the integrated circuit device 10. Therefore, the data driver pad arrangement region PR3 can be provided in the free space in the direction D2 of the data driver blocks DB1 to DBJ, whereby the free space can be effectively utilized. Note that the data signal lines on the panel connected with the pads of the data driver pad arrangement region PR3 are provided in the TFT array section on the array substrate.

In FIG. 14, the grayscale voltage generation circuit block GB and the power supply circuit block PB with a large circuit area are disposed in the direction D3 of the data driver blocks DB1 to DBJ. The logic circuit block LB and the high-speed I/F circuit block HB with a large circuit area are disposed in the direction D1 of the data driver blocks DB1 to DBJ. According to this configuration, the scan driver pad arrangement regions PR1 and PR2 can be provided utilizing the free space provided in the direction D2 of the grayscale voltage generation circuit block GB and the power supply circuit block PB with a large circuit area and the free space provided in the direction D2 of the logic circuit block LB and the high-speed I/F circuit block HB. Therefore, the wiring efficiency can be increased by effectively utilizing the free space, whereby the width of the integrated circuit device 10 in the direction D2 can be reduced. Note that the scan signal lines on the panel connected with the pads of the scan driver pad arrangement regions PR1 and PR2 are provided in the TFT array section on the array substrate.

In FIG. 14, the logic circuit block LB and the high-speed I/F circuit block HB are disposed adjacently. Therefore, the signal line of data received by the high-speed I/F circuit block HB can be connected with the logic circuit block LB along a short path, whereby the layout efficiency can be increased.

In FIG. 14, the high-speed I/F circuit block HB is disposed in the direction D1 of the data driver blocks DB1 to DBJ (i.e., the high-speed I/F circuit block HB is not disposed in the arrangement region of the data driver blocks DB1 to DBJ). Therefore, the grayscale global line and the power supply global line provided over the data driver blocks DB1 to DBJ need not pass over the high-speed I/F circuit block HB. Therefore, the high-speed I/F circuit block HB can be prevented from being adversely affected by noise from these global lines, whereby a malfunction of the high-speed I/F circuit block HB and the like can be prevented.

For example, when mounting the integrated circuit device 10 on a glass substrate (array substrate) using bumps by means of a COG technology, the contact resistance of the bump increases on each end of the integrated circuit device 10. Specifically, since the coefficient of thermal expansion differs between the integrated circuit device 10 and the glass substrate, stress (thermal stress) caused by the difference in coefficient of thermal expansion becomes greater on each end of the integrated circuit device 10 than at the center of the integrated circuit device 10. As a result, the contact resistance of the bump increases with time on each end of the integrated circuit device 10. In particular, the narrower the integrated circuit device 10, the larger the difference in stress between each end and the center, and the greater the increase in contact resistance of the bump on each end.

In the high-speed I/F circuit block HB, the impedance is matched between the transmission side and the reception side in order to prevent signal reflection. Therefore, an impedance mismatch may occur when the contact resistance of the bump connected to the pad of the high-speed I/F circuit block HB increases, whereby the high-speed serial transfer signal quality may deteriorate. Therefore, it is preferable to dispose the high-speed I/F circuit block HB near the center of the integrated circuit device 10, taking the contact resistance into consideration.

In FIG. 14, the high-speed I/F circuit block HB is disposed between the data driver block DBJ and the scan driver block SB2 instead of the rightmost location of the integrated circuit device 10. Therefore, an increase in the contact resistance of the bump can be suppressed within the allowable range as compared with the case of disposing the high-speed I/F circuit block HB on the rightmost side of the integrated circuit device 10. When providing the high-speed I/F circuit block HB in the arrangement region of the data driver blocks DB1 to DBJ taking the contact resistance into consideration to a large extent, the performance of the high-speed I/F circuit block HB decreases due to the effect of noise from the global line. According to the layout method shown in FIG. 14, deterioration in performance due to noise from the global line can be eliminated while suppressing an increase in contact resistance within the allowable range. When noise from the global line is allowable, the high-speed I/F circuit block HB (physical layer circuit and receiver circuit) may be disposed in the I/O region or the like in the direction D4 of the data driver block DBJ, for example.

7. Circuit Configuration Example of Integrated Circuit Device

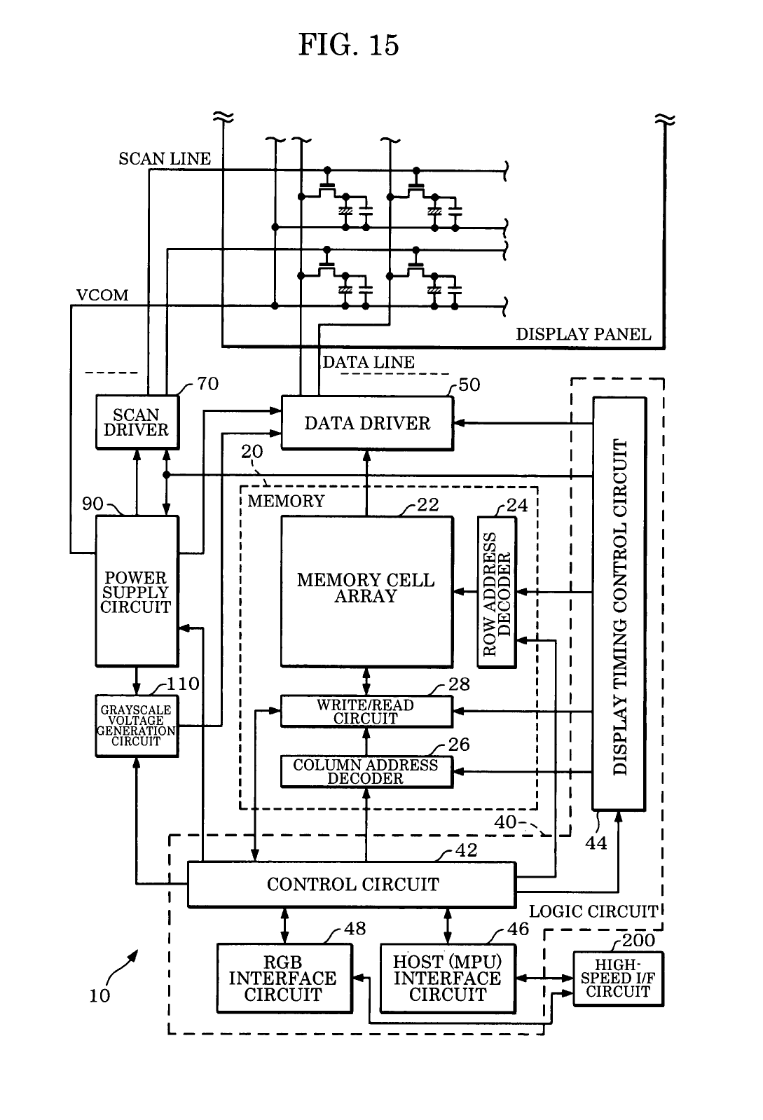

FIG. 15 shows a circuit configuration example of an integrated circuit device (display driver) according to this embodiment. The integrated circuit device according to this embodiment is not limited to the circuit configuration shown in FIG. 15. Various modification may be made such as omitting some elements or adding other elements.

A display panel includes data lines (source lines), scan lines (gate lines), and pixels, each of the pixels being specified by one of the data lines and one of the scan lines. A display operation is implemented by changing the optical properties of an electro-optical element (liquid crystal element in a narrow sense) in each pixel region. The display panel may be formed using an active matrix type panel using a switching element such as a TFT or TFD. The display panel may be a panel other than the active matrix type panel, or may be a panel (e.g. organic EL panel) other than the liquid crystal panel.

A memory 20 (display data RAM) stores image data. A memory cell array 22 includes memory cells, and stores image data (display data) of at least one frame (one screen). A row address decoder 24 (MPU/LCD row address decoder) decodes the row address, and selects the wordline of the memory cell array 22. A column address decoder 26 (MPU column address decoder) decodes the column address, and selects the bitline of the memory cell array 22. A write/read circuit 28 (MPU write/read circuit) writes image data into the memory cell array 22 or reads image data from the memory cell array 22.

A logic circuit 40 (driver logic circuit) generates a control signal for controlling the display timing, a control signal for controlling the data processing timing, and the like. The logic circuit 40 may be formed by automatic placement and routing (e.g., gate array (G/A)).

A control circuit 42 generates various control signals, and controls the entire device. Specifically, the control circuit 42 outputs grayscale adjustment data (gamma correction data) for adjusting grayscale characteristics (gamma characteristics) to a grayscale voltage generation circuit 110, and outputs power supply adjustment data for adjusting the power supply voltage to a power supply circuit 90. The control circuit 42 also controls a memory write/read process using the row address decoder 24, the column address decoder 26, and the write/read circuit 28. A display timing control circuit 44 generates various control signals for controlling the display timing, and controls reading of the image data from the memory 20 into the display panel. A host (MPU) interface circuit 46 realizes a host interface for generating an internal pulse and accessing the memory 20 on each occasion of access from a host. An RGB interface circuit 48 realizes an RGB interface for writing video image RGB data into the memory 20 based on a dot clock signal. The integrated circuit device may be configured to include only one of the host interface circuit 46 and the RGB interface circuit 48.

A data driver 50 is a circuit which generates a data signal for driving the data line of the display panel. Specifically, the data driver 50 receives the image data (grayscale data) from the memory 20, and receives a plurality of (e.g. 256 stages) grayscale voltages (reference voltages) from the grayscale voltage generation circuit 110. The data driver 50 selects the voltage corresponding to the image data from the grayscale voltages, and outputs the selected voltage to the data line of the display panel as the data signal (data voltage).

A scan driver 70 is a circuit which generates a scan signal for driving the scan line of the display panel. Specifically, the scan driver 70 sequentially shifts a signal (enable input/output signal) using a built-in shift register, and outputs a signal obtained by converting the level of the shifted signal to each scan line of the display panel as the scan signal (scan voltage). The scan driver 70 may include a scan address generation circuit and an address decoder. The scan address generation circuit may generate and output a scan address, and the address decoder may decode the scan address to generate the scan signal.

The power supply circuit 90 is a circuit which generates various power supply voltages. Specifically, the power supply circuit 90 increases an input power supply voltage or an internal power supply voltage by a charge-pump method using a boost capacitor and a boost transistor included in a voltage booster circuit provided in the power supply circuit 90. The power supply circuit 90 supplies the resulting voltages to the data driver 50, the scan driver 70, the grayscale voltage generation circuit 110, and the like.

The grayscale voltage generation circuit 110 (gamma correction circuit) is a circuit which generates the grayscale voltage and supplied the grayscale voltage to the data driver 50. Specifically, the grayscale voltage generation circuit 110 may include a ladder resistor circuit which divides the voltage between the high-potential-side power supply and the low-potential-side power supply using resistors, and outputs the grayscale voltages to resistance division nodes. The grayscale voltage generation circuit 110 may also include a grayscale register section into which the grayscale adjustment data is written, a grayscale voltage setting circuit which variably sets (controls) the grayscale voltage output to the resistance division node based on the written grayscale adjustment data, and the like.

A high-speed I/F circuit 200 (serial interface circuit) realizes a high-speed serial transfer through a serial bus. Specifically, the high-speed I/F circuit 200 realizes high-speed serial transfer between the integrated circuit device 10 and the host (host device) by current-driving or voltage-driving differential signal lines of the serial bus.

8. Narrow Integrated Circuit Device

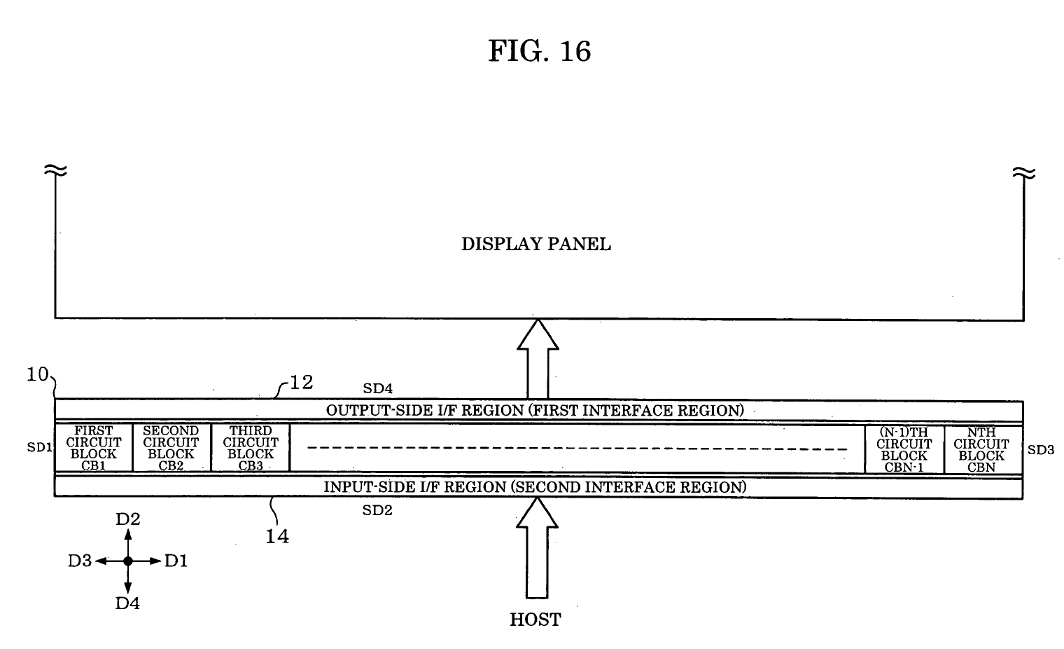

FIG. 16 shows an arrangement example of the integrated circuit device 10. The integrated circuit device 10 includes first to Nth circuit blocks CB1 to CBN (N is an integer equal to or larger than two) disposed along the direction D1. The integrated circuit device 10 includes an output-side I/F region 12 (first interface region in a broad sense) provided along the side SD4 in the direction D2 of the first to Nth circuit blocks CB1 to CBN. The integrated circuit device 10 includes an input-side I/F region 14 (second interface region in a broad sense) provided along the side SD2 in the direction D4 of the first to Nth circuit blocks CB1 to CBN. Specifically, the output-side I/F region 12 is disposed in the direction D2 of the circuit blocks CB1 to CBN without another circuit block or the like provided in between, for example. When the integrated circuit device 10 is used as an intellectual property (IP) core and incorporated in another integrated circuit device, at least one of the output-side I/F region 12 and the input-side I/F region 14 (first and second I/O regions) may be omitted from the integrated circuit device 10.

The output-side (display panel side) I/F region 12 is a region which serves as an interface between the integrated circuit device 10 and the display panel, and may include pads and elements connected to the pads, such as output transistors and protective elements. Specifically, the output-side I/F region 12 may include output transistors for outputting the data signals to the data lines and outputting the scan signals to the scan lines, for example. When the display panel is a touch panel or the like, the output-side I/F region 12 may include input transistors.

The input-side (host-side) I/F region 14 is a region which serves as an interface between the integrated circuit device 10 and a host (MPU, image processing controller, or baseband engine), and may include pads and elements connected to the pads, such as input (input/output) transistors, output transistors, and protective elements. Specifically, the input-side I/F region 14 may include input transistors for inputting signals (digital signals) from the host, output transistors for outputting signals to the host, and the like.

An output-side region or an input-side I/F region may be provided along the short side SD1 or SD3. A bump which serves as an external connection terminal or the like may be provided in the I/F (interface) regions 12 and 14, or may be provided in a region (first to Nth circuit blocks CB1 to CBN) other than the I/F (interface) regions 12 and 14. When providing the bump in the region other than the I/F regions 12 and 14, the bump is formed using a small bump technology (e.g. bump technology using a resin core) other than a gold bump technology.

The first to Nth circuit blocks CB1 to CBN may include at least two (or three) different circuit blocks (circuit blocks having different functions). For example, when the integrated circuit device 10 is a display driver, the circuit blocks CB1 to CBN may include at least two of a data driver block, a memory block, a scan driver block, a logic circuit block, a grayscale voltage generation circuit block, and a power supply circuit block. Specifically, the circuit blocks CB1 to CBN may include at least a data driver block and a logic circuit block, and may further include a grayscale voltage generation circuit block. When the integrated circuit device 10 includes a built-in memory, the circuit blocks CB1 to CBN may include a memory block.

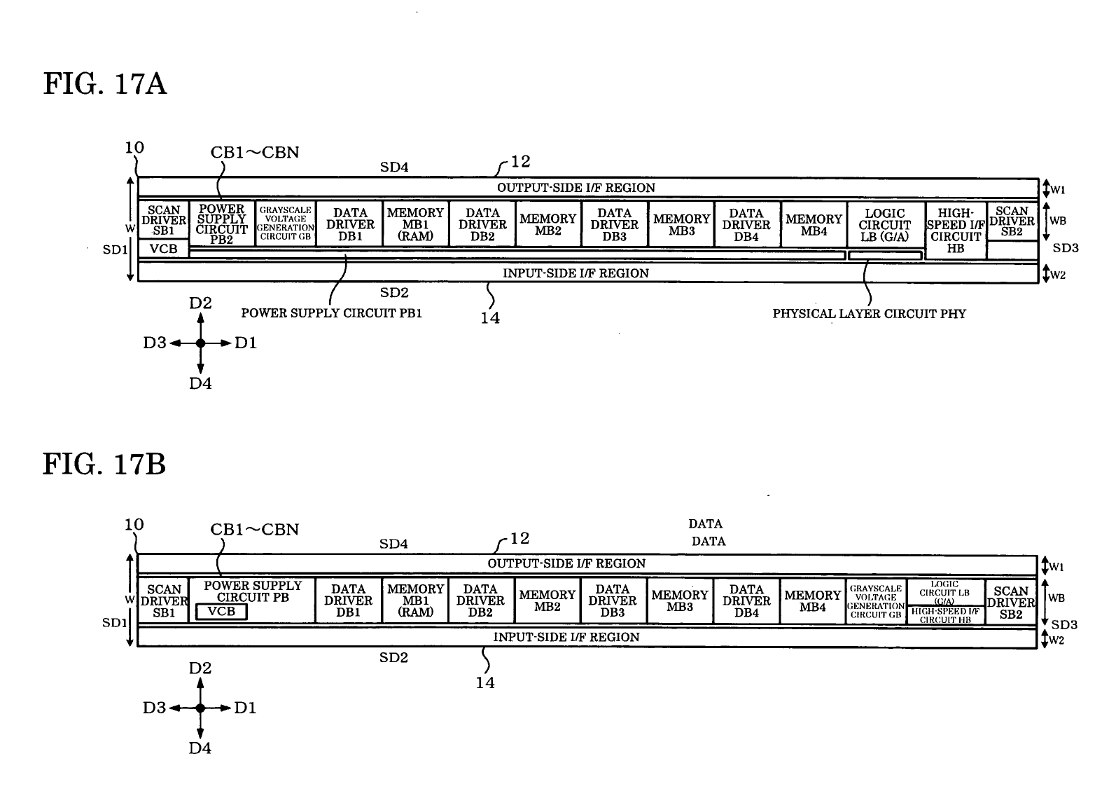

FIGS. 17A and 17B show detailed examples of the planar layout of the integrated circuit device 10. In FIGS. 17A and 17B, the first to Nth circuit blocks CB1 to CBN include first to fourth memory blocks MB1 to MB4 (first to Ith memory blocks in a broad sense; I is an integer equal to or larger than two). The first to Nth circuit blocks CB1 to CBN include first to fourth data driver blocks DB1 to DB4 (first to Ith data driver blocks in a broad sense) respectively disposed adjacent to the first to fourth memory blocks MB1 to MB4 along the direction D1. Specifically, the memory block MB1 and the data driver block DB1 are adjacently disposed along the direction D1, and the memory block MB2 and the data driver block DB2 are adjacently disposed along the direction D1. The memory block MB1 adjacent to the data driver block DB1 stores image data (display data) for the data driver block DB1 to drive the data line, and the memory block MB2 adjacent to the data driver block DB2 stores image data for the data driver block DB2 to drive the data line.

In FIGS. 17A and 17B, scan driver blocks SB1 and SB2 are disposed on either end of the integrated circuit device 10. A modification is also possible in which only one of the scan driver blocks SB1 and SB2 is provided or the scan driver blocks SB1 and SB2 are not provided.

In FIG. 17A, the grayscale voltage generation circuit block GB and the power supply circuit block PB2 are disposed in the direction D3 of the data driver blocks DB1 to DB4 (memory blocks MB1 to MB4). The logic circuit block LB and the high-speed I/F circuit block HB are disposed in the direction D1 of the data driver blocks DB1 to DB4 (MB1 to MB4). The grayscale voltage generation circuit block GB is disposed between the power supply circuit block PB2 and the data driver blocks DB1 to DB4 (MB1 to MB4). The logic circuit block LB and the high-speed I/F circuit block HB are disposed adjacently in the direction D1.

In FIG. 17A, the physical layer circuit PHY is provided in the direction D4 of the logic circuit block LB. A symbol VCB indicates a VCOM generation circuit which generates the common voltage applied to the common electrode.

In FIG. 17A, a narrow power supply circuit block PB1 is disposed along the direction D1 between the circuit blocks CB1 to CBN (data driver blocks DB1 to DB4) and the input-side I/F region 14 (second interface region). The power supply circuit block PB1 is a circuit block which has a long side along the direction D1 and a short side along the direction D2 and has a significantly small width in the direction D2 (narrow circuit block with a width equal to or less than the width WB). The power supply circuit block PB1 may include boost transistors of a voltage booster circuit which increases voltage by a charge-pump operation, a boost control circuit, and the like. The power supply circuit block PB2 may include a power supply register section into which power supply adjustment data for adjusting the power supply voltage is written, a regulator which regulates voltage increased by a voltage booster circuit which increases voltage by a charge pump operation, and the like.

In FIG. 17B, the grayscale voltage generation circuit block GB and the logic circuit block LB are disposed adjacently. The data driver blocks DB1 to DB4 (MB1 to MB4) are disposed between the power supply circuit block PB and the grayscale voltage generation circuit block GB and the logic circuit block LB. This enables the grayscale voltage setting signal from the logic circuit block LB to be input to the grayscale voltage generation circuit block GB along a short path.

In FIG. 17B, the high-speed I/F circuit HB (physical layer circuit) is disposed in the direction D4 of the logic circuit block LB. This enables the differential input signals from the differential input pads to be input to the high-speed I/F circuit block HB along a short path. Moreover, the data pads can be easily used in common by the physical layer circuit PHY and the I/O circuit.

The layout arrangement of the integrated circuit device 10 according to this embodiment is not limited to FIGS. 17A and 17B. For example, the number of memory blocks or data driver blocks may be two, three, or five or more, or the memory block and the data driver block may not be divided into subblocks. A modification is also possible in which the memory block is not adjacent to the data driver block. A configuration may be employed in which the memory block, the scan driver block, the power supply circuit block, or the grayscale voltage generation circuit block is not provided. For example, the memory block may be omitted when the integrated circuit device 10 does not include a memory. The scan driver block may be omitted when the scan driver can be formed on the glass substrate of the display panel. In a color super twisted nematic (CSTN) panel display driver or a thin film diode (TFD) panel display driver, the grayscale voltage generation circuit block may be omitted. A circuit block having a significantly small width in the direction D2 (narrow circuit block with a width equal to or less than the width WB) may be provided between the circuit blocks CB1 to CBN and the output-side I/F region 12 or the input-side I/F region 14. The circuit blocks CB1 to CBN may include a circuit block in which different circuit blocks are arranged in stages along the direction D2. For example, the scan driver circuit and the power supply circuit may be integrated into one circuit block.

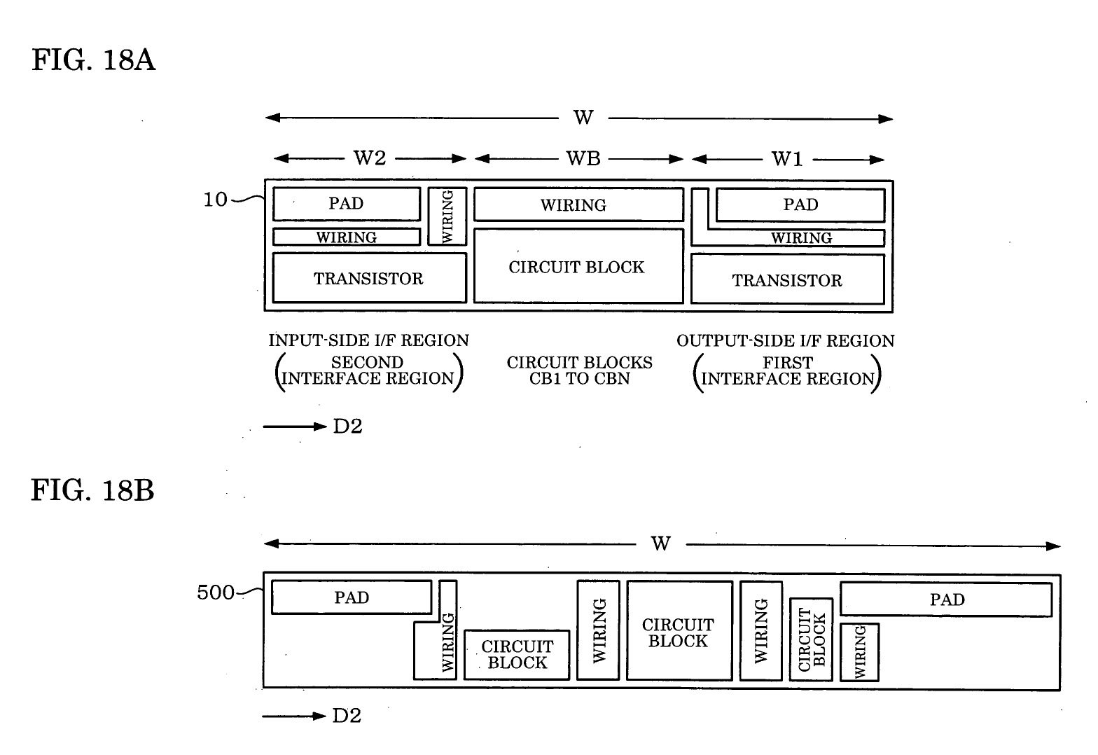

FIG. 18A shows an example of a cross-sectional view of the integrated circuit device 10 along the direction D2. W1, WB, and W2 respectively indicate the widths of the output-side I/F region 12, the circuit blocks CB1 to CBN, and the input-side I/F region 14 in the direction D2. The widths W1, WB, and W2 indicate the widths (maximum widths) of the transistor formation regions (bulk regions or active regions) of the output-side I/F region 12, the circuit blocks CB1 to CBN, and the input-side I/F region 14, respectively, and exclude the bump formation regions. W indicates the width of the integrated circuit device 10 in the direction D2. In this case, the relationship W1+WB+W2≦W<W1+2×WB+W2 is satisfied, for example. Or, since W1+W2<WB is satisfied, W<2×WB is satisfied.

According to the arrangement method shown in FIG. 18B, two or more circuit blocks having a large width in the direction D2 are disposed along the direction D2. Specifically, the data driver block and the memory block are disposed along the direction D2.

In FIG. 18B, the image data from the host is written into the memory block, for example. The data driver block converts the digital image data written into the memory block into an analog data voltage, and drives the data line of the display panel. Therefore, the image data signal flows along the direction D2. In FIG. 18B, the memory block and the data driver block are disposed along the direction D2 corresponding to the signal flow.

However, the arrangement method shown in FIG. 18B has the following problems.

First, a reduction in chip size is required for an integrated circuit device such as a display driver in order to reduce cost. However, if the chip size is reduced by merely shrinking the integrated circuit device using a microfabrication technology, the size of the integrated circuit device is reduced not only in the short side direction but also in the long side direction. This makes mounting difficult due to the narrow pitch.

Second, the configurations of the memory and the data driver of the display driver are changed depending on the type of display panel (amorphous TFT or low-temperature polysilicon TFT), the number of pixels (QCIF, QVGA, or VGA), the specification of the product, and the like. According to the arrangement method shown in FIG. 18B, even if the pad pitch, the cell pitch of the memory, and the cell pitch of the data driver coincide in a certain product, the pitches do not coincide when the configurations of the memory and the data driver are changed. If the pitches do not coincide, an unnecessary wiring region must be formed between the circuit blocks in order to absorb the difference in pitch. As a result, the width of the integrated circuit device in the direction D2 increases, whereby cost is increased due to an increase in the chip area. If the layout of the memory and the data driver is changed so that the pad pitch coincides with the cell pitch in order to avoid such a situation, the development period increases, whereby cost is increased.

According to the arrangement method shown in FIGS. 16 to 17B, the circuit blocks CB1 to CBN are disposed along the direction D1. In FIG. 18A, the transistor (circuit element) can be disposed under the pad (bump) (active surface bump). Moreover, signal lines between the circuit blocks and between the circuit block and the I/F region can be formed using global lines formed in an upper layer (lower layer of the pads) of local lines provided in the circuit blocks. Therefore, the width W of the integrated circuit device 10 in the direction D2 can be reduced while maintaining the length of the integrated circuit device 10 in the direction D1, whereby a narrow chip can be realized.

According to the arrangement method shown in FIGS. 16 to 17B, since the circuit blocks CB1 to CBN are disposed along the direction D1, it is possible to easily deal with a change in the product specification and the like. Specifically, products of various specifications can be designed using a common platform, whereby the design efficiency can be improved. For example, when the number of pixels or the number of grayscales of the display panel is increased or decreased, it is possible to deal with such a situation by merely increasing or decreasing the number of memory blocks or data driver blocks, the image data read count in one horizontal scan period, and the like. For example, when the scan driver can be formed on the display panel such as a low-temperature polysilicon TFT panel, it suffices to remove the scan driver block from the circuit blocks CB1 to CBN. When developing a product without a memory, it suffices to remove the memory block. Even if the circuit block is removed conforming to the specification, the effects on the remaining circuit blocks are minimized, whereby the design efficiency can be improved.

According to the arrangement method shown in FIGS. 16 to 17B, the widths (heights) of the circuit blocks CB1 to CBN in the direction D2 can be adjusted to the width (height) of the data driver block or the memory block, for example. When the number of transistors of each circuit block is increased or decreased, it is possible to deal with such a situation by increasing or decreasing the length of each circuit block in the direction D1. Therefore, the design efficiency can be further improved. For example, when the number of transistors of each circuit block is increased or decreased due to a change in the configuration of the grayscale voltage generation circuit block or the logic circuit block, it is possible to deal with such a situation by increasing or decreasing the length of the grayscale voltage generation circuit block or the logic circuit block in the direction D1.

9. Block Division

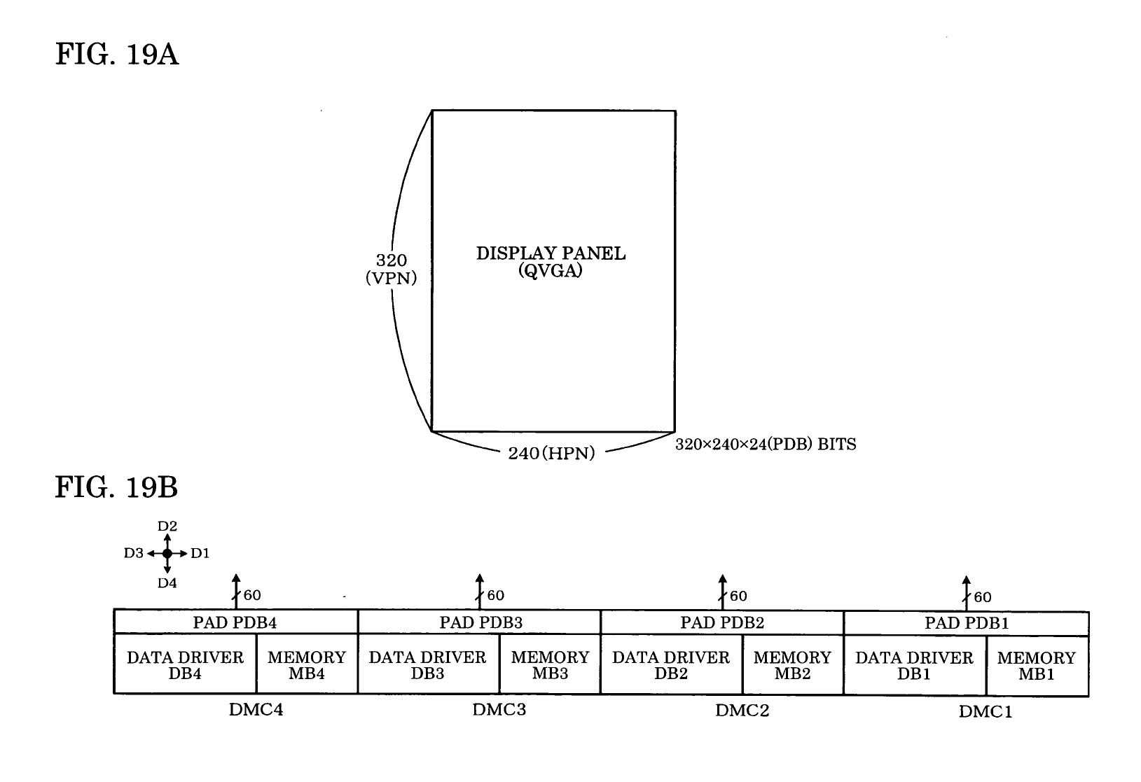

Suppose that the display panel is a QVGA panel in which the number of pixels in the vertical scan direction (data line direction) is VPN=320 and the number of pixels in the horizontal scan direction (scan line direction) is HPN=240, as shown in FIG. 19A. Suppose that the number of bits PDB of image (display) data of one pixel is PDB=24 bits (8 bits each for R, G, and B). In this case, the number of bits of image data necessary for displaying one frame of the display panel is VPN×HPN×PDB=320×240×24 bits. Therefore, the memory of the integrated circuit device stores at least 320×240×24 bits of image data. The data driver outputs data signals of HPN=240 data lines (data signals corresponding to 240×24 bits of image data) to the display panel in units of horizontal scan periods (in units of periods in which one scan line is scanned).

In FIG. 19B, the data driver is divided into four (DBN=4) data driver blocks DB1 to DB4. The memory is also divided into four (MBN=DBN=4) memory blocks MB1 to MB4. Specifically, four driver macrocells DMC1, DMC2, DMC3, and DMC4 are disposed along the direction D1, wherein each of the driver macrocells DMC1, DMC2, DMC3, and DMC4 includes the data driver block, the memory block, and the pad block, for example. Therefore, each of the data driver blocks DB1 to DB4 outputs the data signals of 60 (HPN/DBN=240/4=60) data lines to the display panel in units of horizontal scan periods. Each of the memory blocks MB1 to MB4 stores (VPN×HPN×PDB)/MBN=(320×240×24)/4 bits of image data.

10. Readings in One Horizontal Scan Period

In FIG. 19B, each of the data driver blocks DB1 to DB4 outputs the data signals of 60 data lines (60×3=180 data lines when three data lines are provided for R, G, and B) in one horizontal scan period. Therefore, the image data corresponding to the data signals of 240 data lines must be read from the memory blocks MB1 to MB4 corresponding to the data driver blocks DB1 to DB4 in units of horizontal scan periods.

On the other hand, when the number of bits of image data read in units of horizontal scan periods increases, it is necessary to increase the number of memory cells (sense amplifiers) arranged along the direction D2. As a result, the width W of the integrated circuit device in the direction D2 increases, whereby the width of the chip cannot be reduced. Moreover, since the length of the wordline WL increases, a signal delay occurs in the wordline WL.

In order to solve such problems, it is desirable to employ a method in which the image data stored in the memory blocks MB1 to MB4 is read from the memory blocks MB1 to MB4 into the data driver blocks DB1 to DB4 a plurality of times (RN times) in one horizontal scan period.

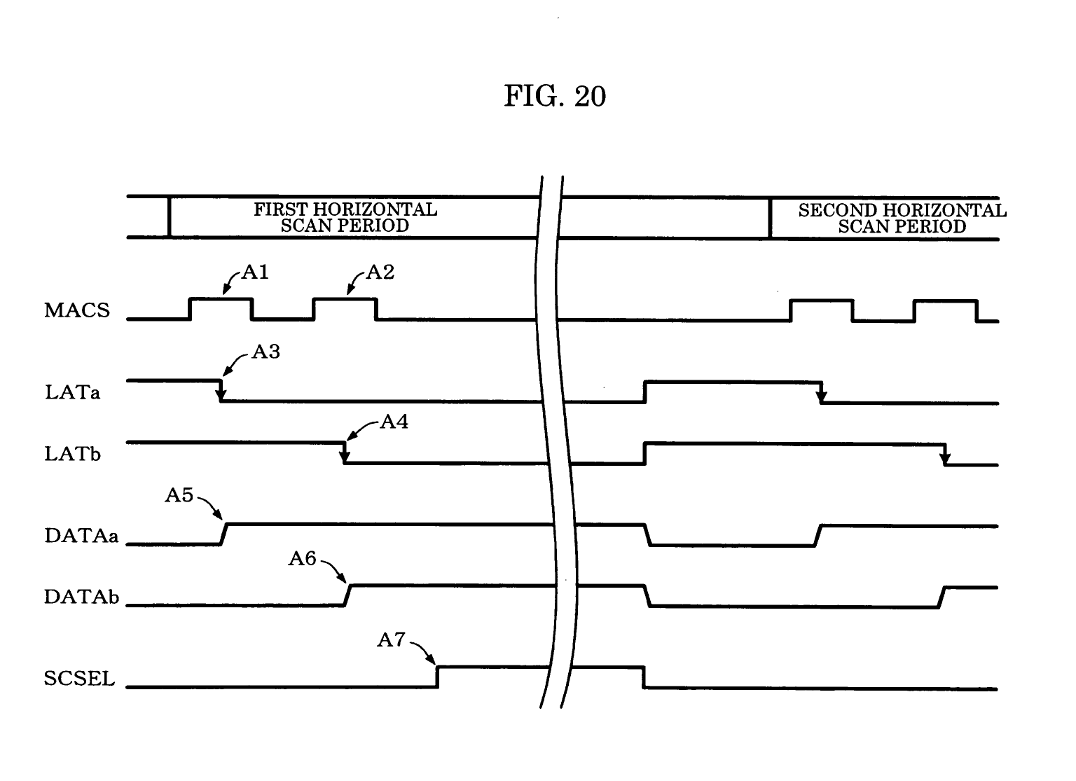

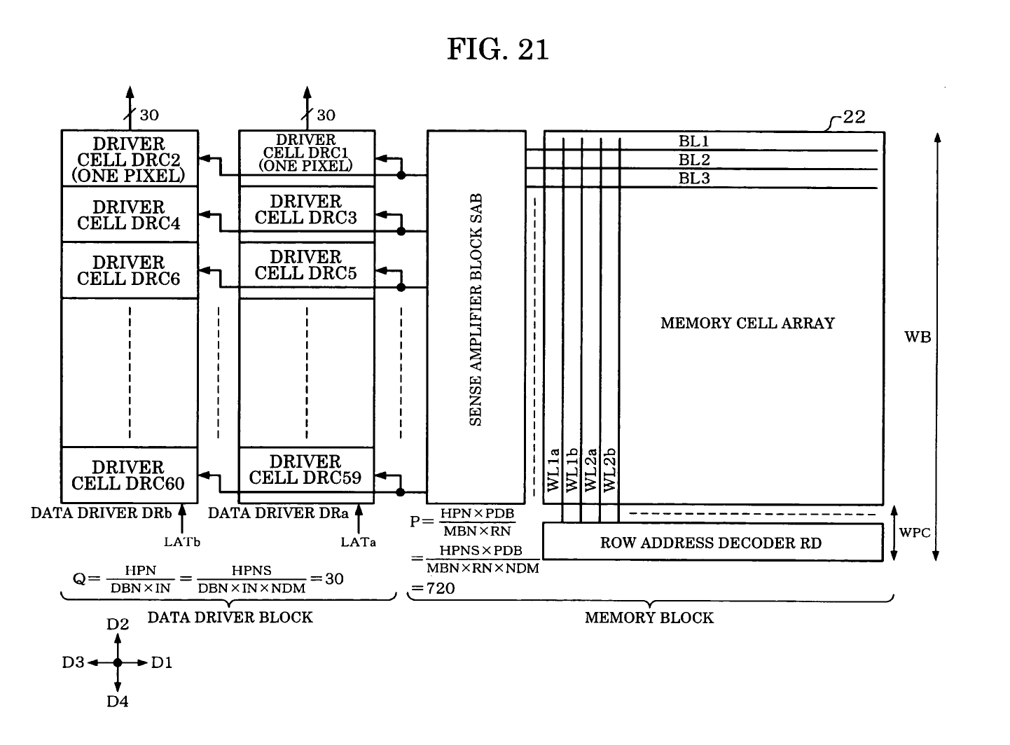

In FIG. 20, a memory access signal MACS (word select signal) goes active (high level) twice (RN=2) in one horizontal scan period, as indicated by A1 and A2, for example. This causes the image data to be read from each memory block into each data driver block twice (RN=2) in one horizontal scan period. Then, data latch circuits of data drivers DRa and DRb shown in FIG. 21 provided in the data driver block latch the read image data based on latch signals LATa and LATb indicated by A3 and A4. Multiplexers of the data drivers DRa and DRb multiplex the latched image data, and D/A converters of the data drivers DRa and DRb subject the multiplexed image data to D/A conversion. Output circuits of the data drivers DRa and DRb output data signals DATAa and DATAb obtained by D/A conversion, as indicated by A5 and A6. A scan signal SCSEL input to the gate of the TFT of each pixel of the display panel goes active, as indicated by A7, and the data signal is input to and held by each pixel of the display panel.

In FIG. 20, the image data is read twice in the first horizontal scan period, and the data signals DATAa and DATAb are output to the data signal output line in the first horizontal scan period. Note that the image data may be read twice and latched in the first horizontal scan period, and the data signals DATAa and DATAb corresponding to the latched image data may be output to the data signal output line in the second horizontal scan period. FIG. 20 shows the case where the read count is RN=2. Note that RN may be equal to or larger than three (RN≧3).

According to the method shown in FIG. 20, the image data corresponding to the data signals of 30 data lines is read from each memory block, and each of the data drivers DRa and DRb outputs the data signals of 30 data lines, as shown in FIG. 21. This allows the data signals of 60 data lines to be output from each data driver block. As described above, it suffices that the image data corresponding to the data signals of 30 data lines be read from each memory block in one read operation in FIG. 20. Therefore, the number of memory cells and sense amplifiers in the direction D2 in FIG. 21 can be reduced as compared with a method of reading the image data only once in one horizontal scan period. As a result, the width of the integrated circuit device in the direction D2 can be reduced, whereby a narrow chip can be realized. In particular, one horizontal scan period is about 52 microseconds in the case of a QVGA display panel. On the other hand, the memory read time is about 40 nanoseconds, which is sufficiently shorter than 52 microseconds. Therefore, even if the read count in one horizontal scan period is increased from one to two or more, the display characteristics are not affected to a large extent.

FIG. 19A shows a QVGA (320×240) display panel. It is possible to deal with a VGA (640×480) display panel by increasing the read count in one horizontal scan period to four (RN=4), for example, whereby the degrees of freedom of the design can be increased.

A plurality of read operations in one horizontal scan period may be achieved using a first method in which the row address decoder (wordline select circuit) selects different wordlines in each memory block in one horizontal scan period or a second method in which the row address decoder (wordline select circuit) selects a single wordline in each memory block a plurality of times in one horizontal scan period. Alternatively, a plurality of read operations in one horizontal scan period may be achieved by combining the first method and the second method.

In FIG. 21, the data driver block includes the data drivers DRa and DRb adjacently disposed along the direction D1. Each of the data drivers DRa and DRb includes driver cells.

When the wordline WL1a of the memory block has been selected and the first image data has been read from the memory block, as indicated by A1 in FIG. 20, the data driver DRa latches the read image data based on the latch signal LATa indicated by A3, and multiplexes the latched image data. The data driver DRa subjects the multiplexed image data to D/A conversion, and outputs the data signal DATAa corresponding to the first image data, as indicated by A5.

When the wordline WL1b of the memory block has been selected and the second image data has been read from the memory block, as indicated by A2 in FIG. 20, the data driver DRb latches the read image data based on the latch signal LATb indicated by A4, and multiplexes the latched image data. The data driver DRb subjects the multiplexed image data to D/A conversion, and outputs the data signal DATAb corresponding to the second image data, as indicated by A6.

Each of the data drivers DRa and DRb outputs the data signals of 30 data lines corresponding to 30 pixels as described above, whereby the data signals of 60 data lines corresponding to 60 pixels are output in total.

A situation in which the width W of the integrated circuit device in the direction D2 is increased due to an increase in the scale of the data driver can be prevented by disposing (stacking) the data drivers DRa and DRb along the direction D1, as shown in FIG. 21. The data driver is configured in various ways depending on the type of display panel. In this case, data drivers of various configurations can be efficiently arranged using the method of disposing the data drivers along the direction D1. FIG. 21 shows the case where the number of data drivers disposed along the direction D1 is two. Note that three or more data drivers may be disposed along the direction D1.

In FIG. 21, each of the data drivers DRa and DRb includes 30 (Q) driver cells disposed along the direction D2. In FIG. 21, the number of pixels of the display panel in the horizontal scan direction (the number of pixels in the horizontal scan direction driven by each integrated circuit device when two or more integrated circuit devices cooperate to drive the data lines of the display panel) is indicated by HPN, the number of data driver blocks (number of block divisions) is indicated by DBN, and the input count of image data to the driver cell in one horizontal scan period is indicated by IN. The input count IN is equal to the image data read count RN in one horizontal scan period described with reference to FIG. 20. In this case, the number Q of driver cells may be expressed as Q=HPN/(DBN×IN). In FIG. 21, since HPN=240, DBN=4, and IN=2, Q=240/(4×2)=30.

The number of subpixels of the display panel in the horizontal scan direction is indicated by HPNS, and the degree of multiplexing of the multiplexer of each driver cell is indicated by NDM. In this case, the number Q of driver cells disposed along the direction D2 may be expressed as Q=HPNS/(DBN×IN×NDM). In FIG. 21, since HPNS=240×3=720, DBN=4, IN=2, and NDM=3, Q=720/(4×2×3)=30. For example, when the degree of multiplexing is increased to NDM=6, Q=720/(4×2×6)=15.

When the width (pitch) of the driver cells in the direction D2 is indicated by WD and the width of the peripheral circuit section (e.g. buffer circuit and wiring region) of the data driver block in the direction D2 is indicated by WPCB, the width WB (maximum width) of the first to Nth circuit blocks CB1 to CBN in the direction D2 may be expressed as Q×WD≦WB<(Q+1)×WD+WPCB. When the width of the peripheral circuit section (e.g. row address decoder RD and wiring region) of the memory block in the direction D2 is indicated by WPC, the width WB (maximum width) of the first to Nth circuit blocks CB1 to CBN in the direction D2 may be expressed as Q×WD≦WB<(Q+1)×WD+WPC.

When the number of pixels of the display panel in the horizontal scan direction is indicated by HPN, the number of bits of image data of one pixel is indicated by PDB, the number of memory blocks is indicated by MBN (=DBN), and the read count of image data from the memory block in one horizontal scan period is indicated by RN. In this case, the number of sense amplifiers (sense amplifiers which output one bit of image data) arranged in the sense amplifier block SAB along the direction D2 may be expressed as P=(HPN×PDB)/(MBN×RN). In FIG. 21, since HPN=240, PDB=24, MBN=4, and RN=2, P=(240×24)/(4×2)=720. The number P is the number of effective sense amplifiers corresponding to the number of effective memory cells, and excludes the number of ineffective sense amplifiers such as sense amplifiers for dummy memory cells.

The number of subpixels of the display panel in the horizontal scan direction is indicated by HPNS, and the degree of multiplexing of the multiplexer of each driver cell is indicated by NDM. In this case, the number P of sense amplifiers disposed along the direction D2 may be expressed as P=(HPNS×PDB)/(MBN×RN×NDM). In FIG. 21, since HPNS=240×3=720, PDB=24, MBN=4, RN=2, and NDM=3, P=(720×24)/(4×2×3)=720.

When the width (pitch) of each sense amplifier of the sense amplifier block SAB in the direction D2 is indicated by WS, the width WSAB of the sense amplifier block SAB (memory block) in the direction D2 may be expressed as WSAB=PXWS. When the width of the peripheral circuit section of the memory block in the direction D2 is indicated by WPC, the width WB (maximum width) of the circuit blocks CB1 to CBN in the direction D2 may also be expressed as P×WS≦WB<(P+PDB)×WS+WPC.

11. Electronic Instrument

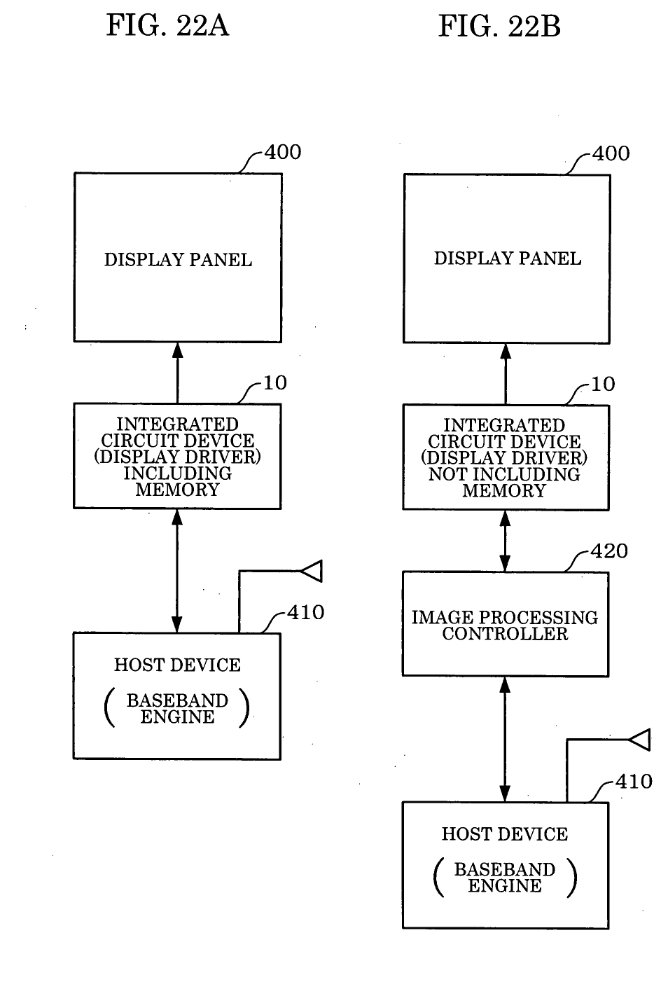

FIGS. 22A and 22B show examples of an electronic instrument (electro-optical device) including the integrated circuit device 10 according to the above embodiment. The electronic instrument may include elements (e.g. camera, operation section, or power supply) other than the elements shown in FIGS. 22A and 22B. The electronic instrument according to this embodiment is not limited to a portable telephone, but may be a digital camera, a PDA, an electronic notebook, an electronic dictionary, a projector, a rear-projection television, a portable information terminal, or the like.

In FIGS. 22A and 22B, a host device 410 is an MPU, a baseband engine, or the like. The host device 410 controls the integrated circuit device 10 (display driver). The host device 410 may also perform a process of an application engine or a baseband engine or a process of a graphic engine, such as compression, decompression, and sizing. An image processing controller 420 shown in FIG. 22B performs a process of a graphic engine such as compression, decompression, or sizing instead of the host device 410.

In FIG. 22A, an integrated circuit device including a memory may be used as the integrated circuit device 10. In this case, the integrated circuit device 10 writes image data from the host device 410 into the memory, and reads the image data from the built-in memory to drive the display panel. In FIG. 22B, an integrated circuit device 10 may be used which does not include a memory. In this case, image data from the host device 410 is written into a built-in memory of the image processing controller 420. The integrated circuit device 10 drives the display panel 400 under control of the image processing controller 420.

Although only some embodiments of the invention have been described in detail above, those skilled in the art would readily appreciate that many modifications are possible in the embodiments without materially departing from the novel teachings and advantages of the invention. Accordingly, such modifications are intended to be included within the scope of the invention. Any term (e.g., output-side I/F region, input-side I/F region, and liquid crystal element) cited with a different term (e.g., first interface region, second interface region, and electro-optical element) having a broader meaning or the same meaning at least once in the specification and the drawings can be replaced by the different term in any place in the specification and the drawings. The pad sharing method described with reference to FIGS. 1 to 13 may be applied not only to the integrated circuit device having the arrangement configuration described with reference to FIGS. 16 to 18A, but also to integrated circuit devices having other arrangement configurations. For example, the pad sharing method may be applied to the integrated circuit device having the arrangement configuration shown in FIG. 18B. It suffices that the CMOS level signal be a signal having an amplitude level larger than that of the small-amplitude differential signal.

What is claimed is:

1. An integrated circuit device comprising:
a plurality of data pads;
a plurality of I/O circuits, each of the plurality of I/O circuits respectively receiving a CMOS level data signal from each of the plurality of data pads;
a high-speed interface circuit block that includes a physical layer circuit and transfers data through a serial bus using differential signals; and
a logic circuit block that receives signals from the high-speed interface circuit block and the plurality of I/O circuits;
at least some of the plurality of data pads being set to be shared pads, and first and second signals forming the differential signals being input to the physical layer circuit through the shared pads.

2. The integrated circuit device as defined in claim 1,
the physical layer circuit including a receiver circuit to which the first and second signals forming the differential signals are input; and
at least the receiver circuit of the physical layer circuit being disposed in an I/O region in which the plurality of I/O circuits are disposed.

3. The integrated circuit device as defined in claim 2,
the plurality of I/O circuits including a first I/O circuit and a second I/O circuit; the shared pads including a first shared pad and a second shared pad,
the first I/O circuit to which a CMOS level data signal from the first shared pad is input and the second I/O circuit to which a CMOS level data signal from the second shared pad is input being disposed in the I/O region; and
the receiver circuit receiving a signal input from the first shared pad as the first signal of the differential signals and receiving a signal input from the second shared pad as the second signal of the differential signals.

4. The integrated circuit device as defined in claim 3,
the receiver circuit being disposed between the first I/O circuit and the second I/O circuit.

5. The integrated circuit device as defined in claim 1,
the shared pads being connected with the plurality of I/O circuits and a receiver circuit of the physical layer circuit;
the receiver circuit being disabled in an MPU interface mode in which the shared pads are used as input pads of the CMOS level data signals; and
the plurality of I/O circuits being disabled in a serial interface mode in which the shared pads are used as input pads of the first and second signals of the differential signals.

6. The integrated circuit device as defined in claim 5,
the integrated circuit device being set in the MPU interface mode in a test mode in case that the integrated circuit device is set in the serial interface mode in a normal mode; and
the logic circuit block performing a test process in the test mode based on CMOS level test signals input from the plurality of data pads through the plurality of I/O circuits.

7. The integrated circuit device as defined in claim 5, further comprising;
a switching terminal that switches the MPU interface mode and the serial interface mode.

8. The integrated circuit device as defined in claim 1,
the shared pads and the plurality of I/O circuits being connected via interconnects when the shared pads are used as input pads of the CMOS level data signals; and
the shared pads and the physical layer circuit being connected via interconnects when the shared pads are used as input pads of the first and second signals of the differential signals.

9. The integrated circuit device as defined in claim 8,
when the integrated circuit device is set in a test mode in a state in which the shared pads and the physical layer circuit are connected via the interconnects, the logic circuit block performing a test process based on CMOS level test signals input through the plurality of I/O circuits from pads among the plurality of data pads other than the shared pads.

10. The integrated circuit device as defined in claim 1,
the logic circuit block receiving data received by the high-speed interface circuit block, and outputting data signals for driving a subdisplay panel to the subdisplay panel through k-bit (k is a positive integer) data pads among the plurality of data pads other than the shared pads.

11. The integrated circuit device as defined in claim 10,
the logic circuit block outputting data transfer control signals to the subdisplay panel through control pads; and
the k-bit data pads being disposed between the shared pads and the control pads.

12. The integrated circuit device as defined in claim 1, comprising:
first to Nth circuit blocks (N is an integer equal to or larger than two) disposed along a first direction when a direction from a first side which is a short side of the integrated circuit device toward a third side opposite to the first side is referred to as a first direction and a direction from a second side which is a long side of the integrated circuit device toward a fourth side opposite to the second side is referred to as a second direction;
the first to Nth circuit blocks including:
at least one data driver block that drives a plurality of data lines of a display panel;
a grayscale voltage generation circuit block that generates grayscale voltages; and
the logic circuit block that transfers grayscale adjustment data for adjusting the grayscale voltage to the grayscale voltage generation circuit block; and
when a direction opposite to the first direction is referred to as a third direction, the grayscale voltage generation circuit block being disposed in the third direction of the data driver block, and the logic circuit block being disposed in the first direction of the data driver block.

13. The integrated circuit device as defined in claim 1, further comprising:
first to Nth circuit blocks (N is an integer equal to or larger than two) disposed along a first direction when a direction from a first side which is a short side of the integrated circuit device toward a third side opposite to the first side is referred to as a first direction and a direction from a second side which is a long side of the integrated circuit device toward a fourth side opposite to the second side is referred to as a second direction;
the first to Nth circuit blocks including:
at least one data driver block that drives a plurality of data lines of a display panel;
a power supply circuit block that generates a power supply voltage; and
the logic circuit block that receives data received by the high-speed interface circuit block and transfers power supply adjustment data for adjusting the power supply voltage to the power supply circuit block; and
when a direction opposite to the first direction is referred to as a third direction, the power supply circuit block being disposed in the third direction of the data driver block, and the logic circuit block being disposed in the first direction of the data driver block.

14. An electronic instrument comprising:
the integrated circuit device as defined in claim 1; and
a display panel driven by the integrated circuit device.

15. An electronic instrument comprising:
the integrated circuit device as defined in claim 5; and
a display panel driven by the integrated circuit device.

16. An electronic instrument comprising:
the integrated circuit device as defined in claim 8; and
a display panel driven by the integrated circuit device.

17. An electronic instrument comprising:
the integrated circuit device as defined in claim 10; and
a display panel driven by the integrated circuit device.

18. An electronic instrument comprising:
the integrated circuit device as defined in claim 12; and
a display panel driven by the integrated circuit device.

19. An electronic instrument comprising:
the integrated circuit device as defined in claim 13; and
a display panel driven by the integrated circuit device.
